(19) United States
(12) Patent Application Publication
(10) Pub. No.: US 2021/0112196 A1
(43) Pub. Date: Apr. 15, 2021

(54) Methods and Systems for Image Capture Operation Assistance Content Display in a Hinged Electronic Device

(71) Applicant: Motorola Mobility LLC, Chicago, IL (US)

(72) Inventors: Boby Iyer, Elmhurst, IL (US); Rahul Desai, Hoffman Estates, IL (US); Eduardo Hideki Tanaka, Campinas (BR); Ryan Kimball, Chicago, IL (US)

(21) Appl. No.: 16/597,207

(22) Filed: Oct. 9, 2019

(51) Int. Cl. H04N 5/232; H05K 5/02; H05K 5/00

(52) U.S. Cl. CPC H04N 5/23222; H05K 5/0017; H05K 5/0226; H04N 5/23219

(57) ABSTRACT

An electronic device includes a first device housing and a second device housing. A hinge couples the first device housing to the second device housing. The first device housing is pivotable about the hinge relative to the second device housing between a closed position and an axially displaced open position. The electronic device includes a display and an imager, each coupled to one of the first device housing or the second device housing. The display and the imager are exposed when the first device housing and the second device housing are in the closed position. One or more processors operable with the imager and the display, in response to detecting an image capture operation using the imager occurring when the electronic device is in the axially displaced open position, temporarily display image capture operation assistance content on the display.

### BACKGROUND

### Technical Field

This disclosure relates generally to methods and systems for electronic devices having imagers, and more particularly to methods and systems for physically deformable electronic devices having imagers.

### Background Art

Mobile electronic communication devices, such as mobile telephones, smart phones, gaming devices, and the like, have become ubiquitous. These devices are used for a variety of purposes, including voice and video telecommunications, sending and receiving text and multimedia messages, Internet browsing, electronic commerce, and social networking. Many are equipped with imagers that can be used to capture images. It would be advantageous to have improved user interfaces to adapt performance, thereby making the image capture process more efficient.

### BRIEF DESCRIPTION OF THE DRAWINGS

FIG. 1 illustrates one explanatory electronic device, along with an explanatory schematic block diagram, in accordance with one or more embodiments of the disclosure.

FIG. 2 illustrates one explanatory electronic device with a first device housing and a second device housing pivoted to a closed position in accordance with one or more embodiments of the disclosure.

FIG. 3 illustrates one explanatory electronic device with a first device housing and a second device housing pivoted to a partially open position in accordance with one or more embodiments of the disclosure.

FIG. 4 illustrates one explanatory electronic device with a first device housing and a second device housing pivoted to an axially displaced open position in accordance with one or more embodiments of the disclosure.

FIG. 5 illustrates another view of one explanatory electronic device with a first device housing and a second device housing pivoted to an axially displaced open position in accordance with one or more embodiments of the disclosure.

FIG. 6 illustrates another explanatory electronic device with a first device housing and a second device housing pivoted to an axially displaced open position in accordance with one or more embodiments of the disclosure.

FIG. 7 illustrates one explanatory electronic device and one or more method steps in accordance with one or more embodiments of the disclosure.

FIG. 8 illustrates one or more explanatory method steps in accordance with one or more embodiments of the disclosure.

FIG. 9 illustrates one explanatory electronic device and one or more method steps in accordance with one or more embodiments of the disclosure.

FIG. 10 illustrates one explanatory electronic device and one or more method steps in accordance with one or more embodiments of the disclosure.

FIG. 11 illustrates one explanatory electronic device and one or more method steps in accordance with one or more embodiments of the disclosure.

FIG. 12 illustrates one explanatory electronic device and one or more method steps in accordance with one or more embodiments of the disclosure.

FIG. 13 illustrates one explanatory electronic device and one or more method steps in accordance with one or more embodiments of the disclosure.

FIG. 14 illustrates one explanatory method in accordance with one or more embodiments of the disclosure.

FIG. 15 illustrates one explanatory electronic device and one or more method steps in accordance with one or more embodiments of the disclosure.

FIG. 16 illustrates one explanatory electronic device and one or more method steps in accordance with one or more embodiments of the disclosure.

FIG. 17 illustrates one explanatory electronic device and one or more method steps in accordance with one or more embodiments of the disclosure.

FIG. 18 illustrates one explanatory electronic device and one or more method steps in accordance with one or more embodiments of the disclosure.

FIG. 19 illustrates one or more embodiments of the disclosure.

Skilled artisans will appreciate that elements in the figures are illustrated for simplicity and clarity and have not necessarily been drawn to scale. For example, the dimensions of some of the elements in the figures may be exaggerated relative to other elements to help to improve understanding of embodiments of the present disclosure.

### DETAILED DESCRIPTION OF THE DRAWINGS

Before describing in detail embodiments that are in accordance with the present disclosure, it should be observed that the embodiments reside primarily in combinations of method steps and apparatus components related to, in response to detecting a bending operation transitioning a first device housing and a second device housing from a closed position to an axially displaced open position, and detecting an image capture operation occurring, presenting image capture operation assistance content on a display of an electronic device. Process descriptions or blocks in a flow chart can be modules, segments, or portions of code that implement specific logical functions of a machine or steps in a process, or alternatively that transition specific hardware components into different states or modes of operation. Alternate implementations are included, and it will be clear that functions may be executed out of order from that shown or discussed, including substantially concurrently or in reverse order, depending on the functionality involved.

It will be appreciated that embodiments of the disclosure described herein may be comprised of one or more conventional processors and unique stored program instructions that control the one or more processors to implement, in conjunction with certain non-processor circuits, some, most, or all of the functions of performing control operations such as the selection and presentation of image capture operation assistance content on a display in response to detecting a hinged electronic device being in the open position when an image capture operation occurs. The non-processor circuits may include, but are not limited to, imaging devices, flash devices, microphones, loudspeakers, acoustic amplifiers, digital to analog converters, signal drivers, clock circuits, power source circuits, and user input devices. As such, these functions may be interpreted as steps of a method to perform the presentation of image capture operation assistance content on a display when an image capture operation occurs after a hinged electronic device is transitioned from a closed position to an axially displaced open position.

Alternatively, some or all functions could be implemented by a state machine that has no stored program instructions, or in one or more application specific integrated circuits (ASICs), in which each function or some combinations of certain of the functions are implemented as custom logic. Of course, a combination of the two approaches could be used. Thus, methods and means for these functions have been described herein. Further, it is expected that one of ordinary skill, notwithstanding possibly significant effort and many design choices motivated by, for example, available time, current technology, and economic considerations, when guided by the concepts and principles disclosed herein will be readily capable of generating such software instructions and programs and ICs with minimal experimentation.

Embodiments of the disclosure do not recite the implementation of any commonplace business method aimed at processing business information, nor do they apply a known business process to the particular technological environment of the Internet. Moreover, embodiments of the disclosure do not create or alter contractual relations using generic computer functions and conventional network operations. Quite to the contrary, embodiments of the disclosure employ methods that, when applied to electronic device having a hinged housing, improve the functioning of the electronic device itself by facilitating the presentation of image capture operation assistance content during image capture operations to improve the overall user experience to overcome problems specifically arising in the realm of the technology associated with image capture in electronic devices having multiple displays.

Embodiments of the disclosure are now described in detail. Referring to the drawings, like numbers indicate like parts throughout the views. As used in the description herein and throughout the claims, the following terms take the meanings explicitly associated herein, unless the context clearly dictates otherwise: the meaning of “a,” “an,” and “the” includes plural reference, the meaning of “in” includes “in” and “on.” Relational terms such as first and second, top and bottom, and the like may be used solely to distinguish one entity or action from another entity or action without necessarily requiring or implying any actual such relationship or order between such entities or actions.

As used herein, components may be “operatively coupled” when information can be sent between such components, even though there may be one or more intermediate or intervening components between, or along the connection path. The terms “substantially”, “essentially”, “approximately”, “about” or any other version thereof, are defined as being close to as understood by one of ordinary skill in the art, and in one non-limiting embodiment the term is defined to be within 10%, in another embodiment within 5%, in another embodiment within 1% and in another embodiment within 0.5%. The term “coupled” as used herein is defined as connected, although not necessarily directly and not necessarily mechanically. Also, reference designators shown herein in parenthesis indicate components shown in a figure other than the one in discussion. For example, talking about a device (10) while discussing figure A would refer to an element, 10, shown in figure other than figure A.

Embodiments of the disclosure provide a hinged electronic device having multiple displays. A first display, sometimes referred to as the interior display or the rear-facing display, is concealed when a first device housing is pivoted about the hinge relative to a second device housing to a closed position. This first display is then revealed when the first device housing is pivoted about the hinge relative to the second device housing from the closed position to an axially displaced open position. A second display, sometimes referred to as an exterior display or front-facing display, is exposed both when the first device housing and the second device housing are pivoted about the hinge to the closed position or the axially displaced open position.

In one or more embodiments, each of the first display and the second display is a high-resolution display. Embodiments of the disclosure contemplate that prior art devices that included a second display employed a low-resolution display for this purpose. Such a low-resolution display lacked richness and was generally ineffective for tasks like presenting images and other complex content. By contrast, embodiments of the disclosure provide electronic devices where both the first display and the second display are rich, high-resolution displays.

As used herein, a high-resolution display refers to displays suitable for the presentation of text, information, and graphics on a mobile device with sufficient granularity as to be easily switched between graphics or text. For example, the high-resolution display would be one suitable for presenting an image in the Joint Photographics Expert Group (JPG) format without distortion. Such displays generally are configured to turn on and off individual pixels by way of a display driver for the presentation of high-resolution information. Examples include organic light emitting diode (OLED) displays, liquid crystal displays (LCD), and plasma display panels (PDP). This is in contrast to low-resolution displays used by the prior art as exterior displays where the presentation of JPG images it is not possible without distortion.

In one or more embodiments, in addition to including the first display and the second display, the hinged electronic device includes at least one imager. In one or more embodiments, the electronic device includes a single imager. This single imager, sometimes known as an exterior imager or front-facing imager, is exposed both when the first device housing and the second device housing are pivoted about the hinge to the closed position or the axially displaced open position. In other embodiments, the electronic device will include at least a first imager and a second imager, with the second imager being an interior or rear-facing imager that is concealed when the first device housing is pivoted about the hinge relative to the second device housing to the closed position, but that is revealed when the first device housing is pivoted about the display relative to the second device housing from the closed position to an axially displaced open position.

Where one imager is included, a person can capture images by activating the imager, directing its lens toward a subject or scene that they wish to capture, and delivering user input causing the imager to capture an image of the subject or scene. Alternatively, they can turn the electronic device around, directing the imager towards himself or herself to take a self image or “selfie.” Where two imagers are included, the person can capture images by activating the front-facing imager, directing its lens toward a subject or scene that they wish to capture, and delivering user input causing the imager to capture an image of the subject or scene. The inclusion of a second imager allows the person to direct the second imager toward himself or herself to capture the selfie without turning the electronic device around. In still other embodiments, the electronic device can include three or more imagers. Thus, electronic devices configured in accordance with embodiments of the disclosure can include multiple imagers at different positions.

In one or more embodiments, both the front facing imager and the front facing display are exposed when the first device housing and the second device housing are in the closed position. In one or more embodiments, one or more processors of the electronic device detect the first device housing pivoting relative to the second device housing from the closed position to the axially displaced open position. In one or more embodiments, when this occurs, the one or more processors enable an image capture operation assistance content presentation feature.

In one or more embodiments, after detecting the first device housing pivoting relative to the second device housing from the closed position to the axially displaced open position, the one or more processors then detect an image capture operation occurring. While the image capture operations can be associated with rear facing or other imagers, in one or more embodiments the one or more processors detect an image capture operation occurring with the front facing or exterior imager, i.e., the imager that is exposed along with the exterior display when the first device housing and the second device housing are pivoted about the hinge to the closed position. Examples of image capture operations include actuation of the front facing imager, receipt of user input directing the front facing imager to capture one or more images or video, the actuation of facial recognition algorithms that employ the front facing imager to analyze light received in its field of view to identify various characteristics of a subject or scene, or other operations.

In one or more embodiments, in response to detecting an image capture operation using the front facing imager occurring after detecting the first device housing pivoting relative to the second device housing from the closed position to the axially displaced open position, the one or more processors temporarily display image capture operation assistance content on the exterior display. Since the exterior display is located on the same side of the electronic device as the front facing camera in one or more embodiments, a subject looking at the front facing camera is able to also see the image capture operation assistance content presented on the exterior display.

Image capture operation assistance content can take any of a number of forms. Examples include review photo image capture operation assistance content, in which a picture taken by the front facing camera is presented on the exterior or front facing display so that the subject of the image can see how they appear in the image. In one or more embodiments, this review photo image capture operation assistance content can be temporarily displayed, such as a period of fifteen or fewer seconds.

In another embodiment, the image capture operation assistance content can comprise call attention image capture operation assistance content. With call attention image capture operation assistance content, a funny image or animation can catch the attention of subjects within the field of view of the front facing camera so that their attention is turned to the electronic device.

In still another embodiment, the image capture operation assistance content can comprise instructional delivery image capture operation assistance content. For example, the instructional delivery image capture operation assistance content can instruct the subject of an image to adopt a particular pose, to say something, to make certain faces, and so forth.

In yet another embodiment, the image capture operation assistance content can comprise smile capture image capture operation assistance content. With smile capture image capture operation assistance content, a humorous or amusing animation or image can be presented on the exterior display requesting the subject of images to smile. This smile capture image capture operation assistance content can be especially engaging with children who may be too young to understand the words, “look here and smile.” Alternatively, for older subjects, the word “SMILE” can be presented on the exterior display, and so forth.

In still another embodiment, the image capture operation assistance content can comprise facial detection image capture operation assistance content. Embodiments of the disclosure contemplate that the presentation of image capture operation assistance content can only be desirable when a person is looking generally toward the electronic device. Disabling the presentation of image capture operation assistance content can conserve battery power when, for example, taking pictures of landscapes as the plants, streams, trees, and clouds are unresponsive to any image capture operation assistance content that may be presented. Accordingly, in one or more embodiments the facial detection image capture operation assistance content comprises the temporary presentation of a detected face on the exterior display.

In another embodiment, the image capture operation assistance content comprises timer countdown image capture operation assistance content. With timer countdown image capture operation assistance content, a numeric or alphanumeric countdown, such as the presentation of the numbers 3-2-1 in succession, can be presented on the exterior display to alert the subjects as to when the exterior imager may capture the image. In one or more embodiments, when the timer countdown reaches a count of zero, the exterior imager captures the image.

In still other embodiments, the image capture operation assistance content can comprise subject gaze image capture operation assistance content. With subject gaze image capture operation assistance content, the exterior display can draw a subject's eyes to a particular location, which may be toward the lens of the exterior camera or somewhere else. If, for example, the person with the electronic device wants to capture an image of a subject gazing up and to the left of the exterior imager as if gazing at the clouds, the exterior imager may present subject gaze image capture operation assistance content in the form of an arrow pointing up and to the left with the words “LOOK HERE.”

In still another embodiment, the image capture operation assistance content can comprise post-image compliment image capture operation assistance content. After capturing an image of a subject, the exterior display may present the words “BEAUTIFUL SHOT” or show an animation of fireworks identifying that the image capture process was highly successful. In other embodiments, the post-image compliment image capture operation assistance content might state, “You're beautiful—don't ever change” or include some other complimentary and inspirational message. In one or more embodiments, this post-image compliment image capture operation assistance content can be temporarily displayed, such as a period of fifteen or fewer seconds. Other examples of post-image compliment image capture operation assistance content will be obvious to those of ordinary skill in the art having the benefit of this disclosure. Still other examples of image capture operation assistance content will also be obvious to those of ordinary skill in the art having the benefit of this disclosure.

The amount of time that the image capture operation assistance content is displayed can vary. For image capture operation assistance content that is displayed after the capture of an image, such as review photo image capture operation assistance content or post-image compliment image capture operation assistance content, this image capture operation assistance content can be presented on the exterior display for a predetermined time, such as three, four, five, ten, or fifteen seconds. Other predetermined time durations will be obvious to those of ordinary skill in the art having the benefit of this disclosure.

For image capture operation assistance content presented before the capture of an image, such as the timer countdown image capture operation assistance content, this image capture operation assistance content can also be presented for a predetermined duration. For example, if the timer countdown image capture operation assistance content comprises the numbers 3-2-1 presented serially, the predetermined time may be a period of five or ten seconds, which allow a subject to see the timer countdown image capture operation assistance content without feeling anxious.

For image capture operation assistance content that is shown during the capture of an image, such as call attention image capture operation assistance content or smile capture image capture operation assistance content, the amount of time this image capture operation assistance content is presented can vary. For example, if the image capture operation assistance content comprises an animation, this animation may be synchronized such that it is playing while the image is captured. Moreover, the image capture operation assistance content can repeat in one or more embodiments. In still another embodiment, cessation of the presentation of image capture operation assistance content can occur when there are no longer any faces detected within the field of view of the external imager. In other embodiments, the expiration of a timer may cause the cessation of the presentation of the image capture operation assistance content. Other examples of termination events causing cessation of the presentation of image capture operation assistance content will be obvious to those of ordinary skill in the art having the benefit of this disclosure.

In one or more embodiments, the image capture operation assistance content can be used in combination. For example, in one embodiment both call attention image capture operation assistance content and review photo image capture operation assistance content can be used when capturing an image. The call attention image capture operation assistance content can be presented for a predetermined amount of time prior to, and during the image capture operation, while the review photo image capture operation assistance content can be presented for a predefined time thereafter. Similarly, both timer countdown image capture operation assistance content and review photo image capture operation assistance content can be used when capturing an image. The timer countdown image capture operation assistance content can be presented for a predetermined amount of time prior to the image capture operation, while the review photo image capture operation assistance content can be presented for a predefined time thereafter.

In still another embodiment, both timer countdown image capture operation assistance content and call attention image capture operation assistance content can be used when capturing an image. The timer countdown image capture operation assistance content can be presented for a predetermined amount of time prior to the image capture operation while the call attention image capture operation assistance content is presented when the image capture operation occurs. In still another embodiment, the call attention image capture operation can precede the timer countdown operation such that the subjects of an image will have their attention called to the electronic device, with the timer counting down thereafter.

Of course, three or more image capture operation assistance content examples can be used in combination. Illustrating by example, if timer countdown image capture operation assistance content, call attention image capture operation assistance content, and photo review image capture operation assistance content are used in combination, the timer countdown image capture operation assistance content can be presented for a predetermined amount of time prior to the image capture operation while the call attention image capture operation assistance content is presented when the image capture operation occurs. Thereafter, the photo review image capture operation assistance content can be displayed for a predetermined duration, such as five to ten seconds. Other combinations of image capture operation assistance content suitable for use with embodiments of the disclosure will be obvious to those of ordinary skill in the art having the benefit of this disclosure. For example, the three operations in this illustration can occur in other orders.

In one or more embodiments, the presentation of image capture operation assistance content is supported in both portrait and landscape mode, just as is the image capture operation. Thus, when an electronic device is held in portrait mode, the image capture operation assistance content can be presented in portrait mode. By contrast, when the electronic device is rotated to landscape mode, the presentation of the image capture operation assistance content can rotate as well so that the subject always views the image capture operation assistance content right-side up.

In one or more embodiments, a user can be prompted regarding which image capture operation assistance content or combinations of image capture operation assistance content they desire to employ during the image capture process. For instance, in one or more embodiments, upon actuating an imager a menu is presented on the interior display allowing a user to select one or more image capture operation assistance content options from a plurality of image capture operation assistance content options.

In other embodiments, automatic scene detection performed by the one or more processors of the electronic device can be used to select one or more image capture operation assistance content options from a plurality of image capture operation assistance content options. If, for example, the subject of a photo is detected as being a child, a call attention image capture operation assistance content option may comprise an animation of the cartoon dog, Buster, playing with his friends Mac and Henry. By contrast, if the subject of the photo is detected as being a group of adults, the image capture operation assistance content option may be a video of people drinking wine on the beach after taking a successful photo together, and so forth.

In one or more embodiments, the presentation of image capture operation assistance content can be enabled and disabled as a function of the physical state of the electronic device. If the first device housing and the second device housing are pivoted about the hinge from the axially displaced open position to the closed position, in one or more embodiments the presentation of image capture operation assistance content is disabled. By contrast, if the first device housing and the second device housing are pivoted about the hinge from the closed position to the axially displaced open position, in one or more embodiments the presentation of image capture operation assistance content is enabled.

In one or more embodiments, light input can be used to enable and disable the presentation of image capture operation assistance content in addition to, or instead of, the physical state of the electronic device. If, for example, the electronic device is in a low light environment, in one or more embodiments the presentation of image capture operation assistance content is disabled. This prevents the presentation of image capture operation assistance content in environments such as movie theaters. By contrast, if the electronic device is in a high light environment, in one or more embodiments the presentation of image capture operation assistance content is enabled, and so forth.

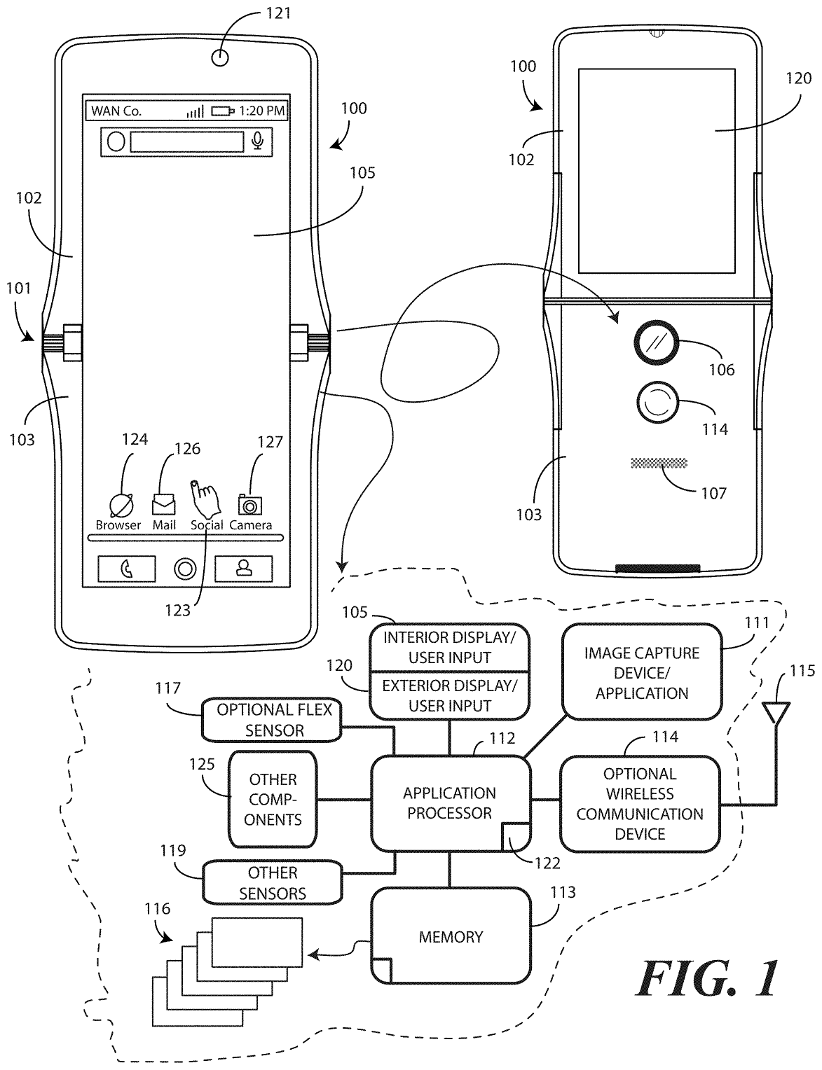

Turning now to FIG. 1, illustrated therein is one explanatory electronic device 100 configured in accordance with one or more embodiments of the disclosure. The electronic device 100 of FIG. 1 is a portable electronic device. For illustrative purposes, the electronic device 100 is shown as a smartphone. However, the electronic device 100 could be any number of other devices as well, including tablet computers, gaming devices, multimedia players, and so forth. Still other types of electronic devices can be configured in accordance with one or more embodiments of the disclosure as will be readily appreciated by those of ordinary skill in the art having the benefit of this disclosure.

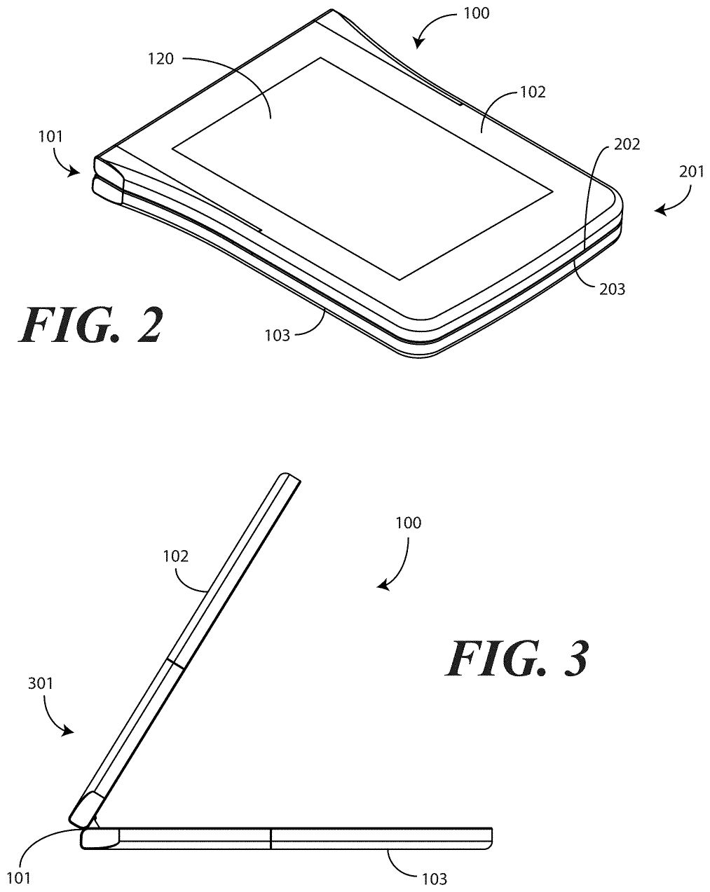

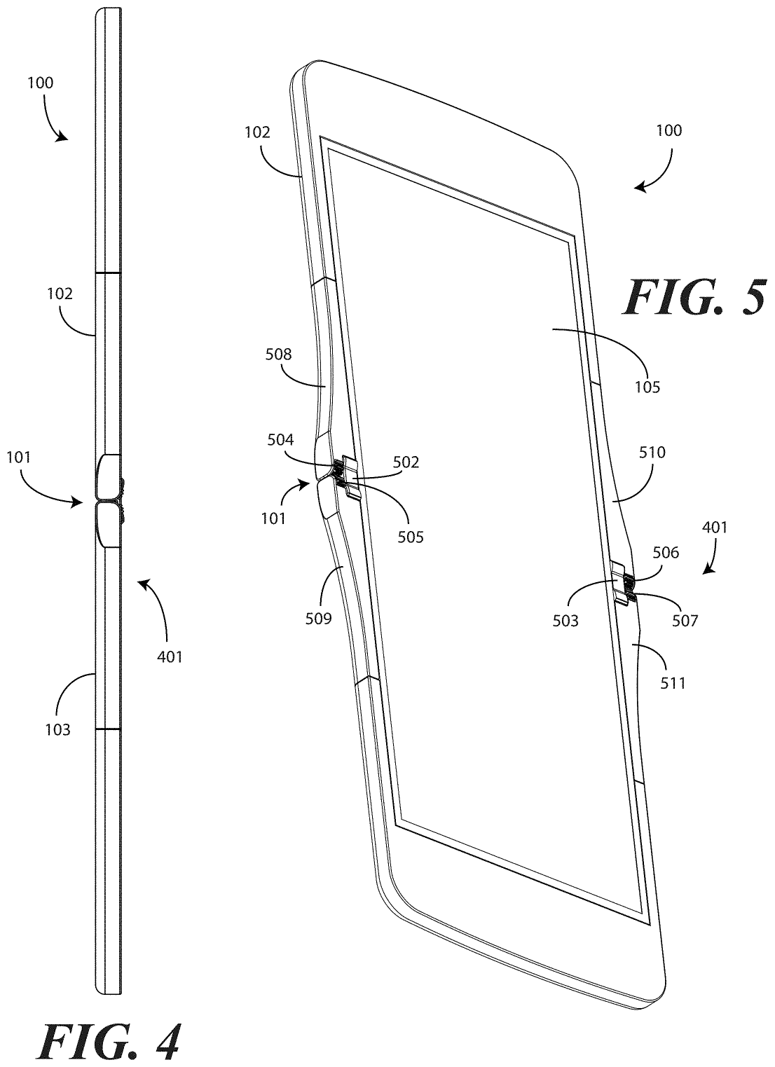

The electronic device 100 includes a first device housing 102 and a second device housing 103. In one or more embodiments, a hinge 101 couples the first device housing 102 to the second device housing 103. In one or more embodiments, the first device housing 102 is selectively pivotable about the hinge 101 relative to the second device housing 103. For example, in one or more embodiments the first device housing 102 is selectively pivotable about the hinge 101 between a closed position, shown and described below with reference to FIG. 2, a partially open position, shown and described below with reference to FIG. 3, and an open position, shown and described below with reference to FIGS. 4-5.

In one or more embodiments the first device housing 102 and the second device housing 103 are manufactured from a rigid material such as a rigid thermoplastic, metal, or composite material, although other materials can be used. Still other constructs will be obvious to those of ordinary skill in the art having the benefit of this disclosure. In the illustrative embodiment of FIG. 1, the electronic device 100 includes a single hinge 101. However, in other embodiments two or more hinges can be incorporated into the electronic device 100 to allow it to be folded in multiple locations.

While the illustrative electronic device 100 of FIG. 1 includes a hinge 101, embodiments of the disclosure are not so limited. In other embodiments, the electronic device 100 will be bendable, but will not include a hinge 101, such as when the first device housing 102 and the second device housing 103 are manufactured from bendable materials. In still other embodiments, the electronic device 100 can be bendable via a combination of hinge components and non-hinge components.

Illustrating by example, in another embodiment the electronic device 100 of FIG. 1 includes a single housing. In one or more embodiments, that housing is flexible. In one embodiment, the housing may be manufactured from a malleable, bendable, or physically deformable material such as a flexible thermoplastic, flexible composite material, flexible fiber material, flexible metal, organic or inorganic textile or polymer material, or other materials. The housing could be formed from a single flexible housing member or from multiple flexible housing members.

In other embodiments, the housing could be a composite of multiple components. For instance, in another embodiment the housing could be a combination of rigid segments connected by hinges or flexible materials. Still other constructs will be obvious to those of ordinary skill in the art having the benefit of this disclosure.

The illustrative electronic device 100 of FIG. 1 includes multiple displays. A first display 105, also referred to as the interior display or the rear-facing display, is concealed when the first device housing 102 is pivoted about the hinge 101 relative to the second device housing 103 to a closed position. For example, the first display 105 is concealed in FIG. 2 below. This first display 105 is then revealed when the first device housing 102 is pivoted about the hinge 101 relative to the second device housing 103 from the closed position to an axially displaced open position. Thus, the first display 105 is revealed as the electronic device 100 transitions from the closed position of FIG. 2 to the open position of FIGS. 4-5.

In one or more embodiments, the electronic device 100 also includes at least a second display 120. In the illustrative embodiment of FIG. 1, the second display 120 can be referred to as an exterior display or front-facing display, as the second display 120 is exposed both when the first device housing 102 and the second device housing 103 are pivoted about the hinge 101 to the closed position or the axially displaced open position. Thus, the second display 120 is exposed both in the axially displaced open position of FIG. 1 and the closed position of FIG. 2. In one or more embodiments, each of the first display 105 and the second display 120 is a high-resolution display.

While shown coupled to the first device housing 102, it should be noted that the second display 120 could be coupled to either of the first device housing 102 or the second device housing 103. In other embodiments, the second display 120 can be coupled to the first device housing 102, while a third display (not shown) is coupled to the second device housing 103. Thus, electronic devices configured in accordance with embodiments of the disclosure can include displays situated at different positions.

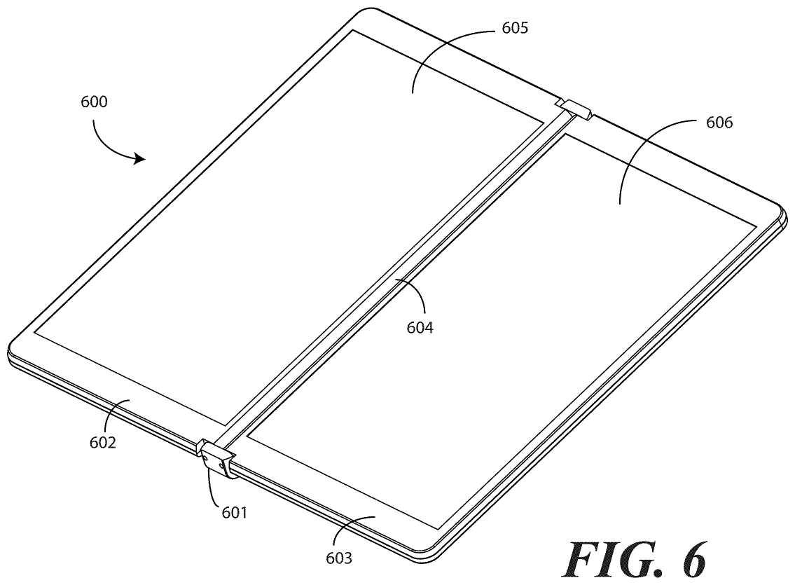

As with the second display 120, the first display 105 can also be coupled to either or both of the first device housing 102 or the second device housing 103. In this illustrative embodiment, the first display 105 is coupled to both the first device housing 102 and the second device housing 103 and spans the hinge 101. In other embodiments, as will be described below with reference to FIG. 6, the “first” display can be two displays, with one coupled to the first device housing 102 and another coupled to the second device housing 103. In either case, this first display 105 is considered to be an “interior” display because it is concealed when the first device housing 102 and the second device housing 103 are in the closed position.

In one or more embodiments, either or both of first display 105 or second display 120 can be touch-sensitive. Where this is the case, users can deliver user input to one or both of the first display 105 or the second display 120 by delivering touch input from a finger, stylus, or other objects disposed proximately with the first display 105 or the second display 120.

In the illustrative embodiment of FIG. 1, since the first display 105 spans the hinge 101, it is configured to be flexible. For instance, in one embodiment the first display 105 is configured as an organic light emitting diode (OLED) display fabricated on a flexible plastic substrate. This allows the first display 105 to be flexible so as to deform when the first device housing 102 pivots about the hinge 101 relative to the second device housing 103. However, it should be noted that other types of displays would be obvious to those of ordinary skill in the art having the benefit of this disclosure. As will be described below with reference to FIG. 6, in other embodiments conventional, rigid displays can be disposed to either side of the hinge rather than using a flexible display.

In one or more embodiments, the first display 105 is configured as an OLED constructed on flexible plastic substrates to allow the first display 105 to bend in accordance with various bending radii. For example, some embodiments allow bending radii of between thirty and six hundred millimeters to provide a bendable display. Other substrates allow bending radii of around five millimeters to provide a display that is foldable through active bending. Other displays can be configured to accommodate both bends and folds. In one or more embodiments the first display 105 may be formed from multiple layers of flexible material such as flexible sheets of polymer or other materials.

In this illustrative embodiment, the first display 105 is coupled to the first device housing 102 and the second device housing 103. Accordingly, the first display 105 spans the hinge 101 in this embodiment. In one or more embodiments, the first display 105 can instead be coupled to one, or two, spring-loaded, slidable trays that situate within one or both of the first device housing 102 and the second device housing 103. The use of one or two slidable trays advantageously allows the first display 105 to be placed in tension when the electronic device 100 is in the open position. This causes the first display 105 to be flat, rather than wavy due to mechanical memory effects, when the electronic device 100 is in the open position.

Features can be incorporated into the first device housing 102 and/or the second device housing 103. Examples of such features include imager 106, which in this embodiment is an exterior or front facing imager. The imager 106, which can be any number of types of image capture devices, has its lens situated such that it is directed away from a user who is holding the electronic device 100 and facing the first display 105. This allows the imager 106 to receive light directed toward the electronic device 100 from a location in front of the user when the user is holding the electronic device 100 and facing the first display 105.

Instead of, or alternatively in addition to, the imager 106, a second, rear facing imager 121 can be positioned on the interior side of the electronic device 100 to receive light and images directed toward the first display 105. When a user is holding the electronic device 100 and looking at the first display, this second, rear facing imager 121 can be used to take a selfie without turning the electronic device 100 around. While two imagers are shown in the illustrative embodiment of FIG. 1, it should be noted that embodiments of the disclosure can include additional imagers mounted in different positions that can be actuated to capture images from different angles.

Other examples of features that can be incorporated into the first device housing 102 and/or the second device housing 103 include an optional speaker port 107. While shown situated on the exterior of the electronic device 100 in FIG. 1, the optional speaker port 107 could also be placed on the interior side as well. In this illustrative embodiment, a user interface component 114, which may be a button or touch sensitive surface, can also be disposed along the exterior side of the second device housing 103. As noted, any of these features shown being disposed on the exterior side of the electronic device 100 could be located elsewhere, such as on the interior side or minor sides in other embodiments.

A block diagram schematic of the electronic device 100 is also shown in FIG. 1. In one embodiment, the electronic device 100 includes one or more processors 112. In one embodiment, the one or more processors 112 can include an application processor and, optionally, one or more auxiliary processors. One or both of the application processor or the auxiliary processor(s) can include one or more processors. One or both of the application processor or the auxiliary processor(s) can be a microprocessor, a group of processing components, one or more ASICs, programmable logic, or other type of processing device.

The application processor and the auxiliary processor(s) can be operable with the various components of the electronic device 100. Each of the application processor and the auxiliary processor(s) can be configured to process and execute executable software code to perform the various functions of the electronic device 100. A storage device, such as memory 113, can optionally store the executable software code used by the one or more processors 112 during operation.

The one or more processors 112 can optionally include, and be operable with, a timer 122. For example, when a user delivers a user command for the imager 106 or second imager 121 to capture an image, the one or more processors 112 can initiate and/or actuate the timer 122. The use of the timer 122 can be used in association with the presentation of image capture operation assistance content, such as when the image capture operation assistance content comprises timer countdown image capture operation assistance content in the form of a numeric countdown animation, as will be described in more detail below.

In one or more embodiments, the electronic device 100 also includes an image capture application module 111 that identifies actuation of the imager 106 and/or second imager 121 and/or image capture operations. For example, the image capture application module 111 can detect user actuation of the imager 106 and/or second imager 121. The image capture application module 111 can also include a facial recognition module that analyzes images captured by the imager 106 and/or second imager 121 to identify facial characteristics present in images captured by the imager 106 and/or second imager 121. In one or more embodiments, in response to the image capture application module 111 identifying these or other image capture operations, the one or more processors can cause the presentation of image capture assistance content as will be described in more detail below.

In this illustrative embodiment, the electronic device 100 also includes a communication circuit 114 that can be configured for wired or wireless communication with one or more other devices or networks. The networks can include a wide area network, a local area network, and/or personal area network. Examples of wide area networks include GSM, CDMA, W-CDMA, CDMA-2000, iDEN, TDMA, 2.5 Generation 3GPP GSM networks, 3rd Generation 3GPP WCDMA networks, 3GPP Long Term Evolution (LTE) networks, and 3GPP2 CDMA communication networks, UMTS networks, E-UTRA networks, GPRS networks, iDEN networks, and other networks.

The communication circuit 114 may also utilize wireless technology for communication, such as, but are not limited to, peer-to-peer or ad hoc communications such as HomeRF, Bluetooth and IEEE 802.11 (a, b, g or n), and other forms of wireless communication such as infrared technology. The communication circuit 114 can include wireless communication circuitry, one of a receiver, a transmitter, or transceiver, and one or more antennas 115.

In one embodiment, the one or more processors 112 can be responsible for performing the primary functions of the electronic device 100. For example, in one embodiment the one or more processors 112 comprise one or more circuits operable with one or more user interface devices, which can include the display 105, to present, images, video, or other presentation information to a user. The executable software code used by the one or more processors 112 can be configured as one or more modules 116 that are operable with the one or more processors 112. Such modules 116 can store instructions, control algorithms, logic steps, and so forth.

In one embodiment, the one or more processors 112 are responsible for running the operating system environment of the electronic device 100. The operating system environment can include a kernel and one or more drivers, and an application service layer, and an application layer. The operating system environment can be configured as executable code operating on one or more processors or control circuits of the electronic device 100.

The application layer can be responsible for executing application service modules. The application service modules may support one or more applications or “apps.” Examples of applications shown in FIG. 1 include an Internet browser application 124, an electronic mail application 126, a social media application 123, and an image capture application 127. These applications are illustrative only, as numerous others will be obvious to those of ordinary skill in the art having the benefit of this disclosure. The applications of the application layer can be configured as clients of the application service layer to communicate with services through application program interfaces (APIs), messages, events, or other inter-process communication interfaces. Where auxiliary processors are used, they can be used to execute input/output functions, actuate user feedback devices, and so forth.

In one embodiment, the electronic device 100 includes one or more flex sensors 117, operable with the one or more processors 112, to detect a bending operation that causes the first device housing 102 to pivot about the hinge 101 relative to the second device housing 103, thereby transforming the electronic device 100 into a deformed geometry, such as that shown in FIGS. 2-3. The inclusion of flex sensors 117 is optional, and in some embodiment flex sensors 117 will not be included.

In one embodiment, the flex sensors 117 comprise passive resistive devices manufactured from a material with an impedance that changes when the material is bent, deformed, or flexed. By detecting changes in the impedance as a function of resistance, the one or more processors 112 can use the one or more flex sensors 117 to detect bending of the first device housing 102 about the hinge 101 relative to the second device housing 103. In one or more embodiments, each flex sensor 117 comprises a bi-directional flex sensor that can detect flexing or bending in two directions. In one embodiment, the one or more flex sensors 117 have an impedance that increases in an amount that is proportional with the amount it is deformed or bent.

In one embodiment, each flex sensor 117 is manufactured from a series of layers combined together in a stacked structure. In one embodiment, at least one layer is conductive, and is manufactured from a metal foil such as copper. A resistive material provides another layer. These layers can be adhesively coupled together in one or more embodiments. The resistive material can be manufactured from a variety of partially conductive materials, including paper-based materials, plastic-based materials, metallic materials, and textile-based materials. In one embodiment, a thermoplastic such as polyethylene can be impregnated with carbon or metal so as to be partially conductive, while at the same time being flexible.

In one embodiment, the resistive layer is sandwiched between two conductive layers. Electrical current flows into one conductive layer, through the resistive layer, and out of the other conductive layer. As the flex sensor 117 bends, the impedance of the resistive layer changes, thereby altering the flow of current for a given voltage. The one or more processors 112 can detect this change to determine an amount of bending. Taps can be added along each flex sensor 117 to determine other information, including the amount of bending, the direction of bending, and so forth. The flex sensor 117 can further be driven by time-varying signals to increase the amount of information obtained from the flex sensor 117 as well. While a multi-layered device as a flex sensor 117 is one configuration suitable for detecting at least a bending operation occurring to deform the electronic device 100 and a geometry of the electronic device 100 after the bending operation, others can be used as well. Other types of flex sensors 117 will be obvious to those of ordinary skill in the art having the benefit of this disclosure.

In one embodiment, the one or more processors 112 may generate commands or execute control operations based on information received from the various sensors, including the one or more flex sensors 117, the user interface 118, which includes display 105 and display 120, or the other sensors 119. Illustrating by example, in one or more embodiments the one or more processors 112 enable the image capture application module 111 when the one or more flex sensors 117 indicate that the first device housing 102 has pivoted about the hinge 101 relative to the second device housing 103 from the closed position to the axially displaced open position.

The one or more processors 112 may also generate commands or execute control operations based upon information received from a combination of the one or more flex sensors 117, the user interface 118, or the other sensors 119. Alternatively, the one or more processors 112 can generate commands or execute control operations based upon information received from the one or more flex sensors 117 or the user interface 118 alone. Moreover, the one or more processors 112 may process the received information alone or in combination with other data, such as the information stored in the memory 113.

The one or more other sensors 119 may include a microphone, an earpiece speaker, a second loudspeaker (disposed beneath speaker port 107), and a user interface component such as a button or touch-sensitive surface. The one or more other sensors 119 may also include key selection sensors, proximity sensors, a touch pad sensor, a touch screen sensor, a capacitive touch sensor, a light sensor, and one or more switches. Touch sensors may used to indicate whether any of the user actuation targets present on the display 105 are being actuated. Alternatively, touch sensors disposed in the electronic device 100 can be used to determine whether the electronic device 100 is being touched at side edges or major faces of the first device housing 102 or the second device housing 103. The touch sensors can include surface and/or housing capacitive sensors in one embodiment. The other sensors 119 can also include audio sensors and video sensors (such as a camera).

The other sensors 119 can also include motion detectors, such as one or more accelerometers or gyroscopes. For example, an accelerometer may be embedded in the electronic circuitry of the electronic device 100 to show vertical orientation, constant tilt and/or whether the electronic device 100 is stationary. The measurement of tilt relative to gravity is referred to as “static acceleration,” while the measurement of motion and/or vibration is referred to as “dynamic acceleration.” A gyroscope can be used in a similar fashion.

Other components 125 operable with the one or more processors 112 can include output components such as video outputs, audio outputs, and/or mechanical outputs. Examples of output components include audio outputs such as speaker port 107, earpiece speaker, or other alarms and/or buzzers and/or a mechanical output component such as vibrating or motion-based mechanisms. Still other components will be obvious to those of ordinary skill in the art having the benefit of this disclosure.

It is to be understood that FIG. 1 is provided for illustrative purposes only and for illustrating components of one electronic device 100 in accordance with embodiments of the disclosure, and is not intended to be a complete schematic diagram of the various components required for an electronic device. Therefore, other electronic devices in accordance with embodiments of the disclosure may include various other components not shown in FIG. 1, or may include a combination of two or more components or a division of a particular component into two or more separate components, and still be within the scope of the present disclosure.

Turning now to FIG. 2, illustrated therein is the electronic device 100 in a closed state. In this state, the first device housing 102 has been pivoted about the hinge 101 toward the second device housing 103 to a closed position 201. When in the closed position 201, a front surface 202 of the first device housing 102 abuts a front surface 203 of the second device housing 103. When in the closed position 201, the exterior display, i.e., second display 120, is visible, exposed, and accessible by a user. By contrast, when in the closed position 201, the interior display, i.e., first display (105), is concealed, is not visible, and is inaccessible by a user. Effectively, in the closed position 201 the first device housing 102 and the second device housing 103 are analogous to clam shells that have been shut by the claim, thereby giving rise to the “clamshell” style of device.

Turning now to FIG. 3, the electronic device 100 is shown being transitioned from the closed position (201) of FIG. 2 to a partially opened position. Specifically, the first device housing 102 is pivoting about the hinge 101 away from the second device housing 103 toward, but not fully yet to, an open position where the first device housing 102 is axially displaced about the hinge 101 from the second device housing 103. The position shown in FIG. 3 can be referred to as a “tent position” 301.

Turning now to FIGS. 4 and 5, illustrated therein is the electronic device 100 in an open position 401 where the first device housing 102 is rotated about the hinge 101 so as to become axially displaced from the second device housing 103. In the open position, the first device housing 102 is rotated about the hinge 101 180-degrees out of phase with the second device housing 103 such that the first device housing 102 and the second device housing 103 effectively define a plane. The first display 105, being flexible, has been transitioned from a bent position into the elongated flat position show in FIG. 5. In one or more embodiments this occurs due to the action of one or more slidable trays (mentioned above), which can be disposed within one or both of the first device housing 102 and the second device housing 103.

Turning now to FIG. 6, illustrated therein is another electronic device 600 configured in accordance with one or more embodiments of the disclosure. The electronic device 600 of FIG. 6 is similar to that of FIG. 1, in that it includes a first device housing 602 and a second device housing 603, and a hinge 601. The hinge 601 couples the first device housing 602 to the second device housing 603. The first device housing 602 is pivotable about the hinge 601 relative to the second device housing 603 between an axially displaced open position and a closed position, as previously described.

In one or more embodiments, the electronic device 600 also includes an exterior display attached to one of the first device housing 602 or the second device housing 603, as previously described above with reference to second display (120) of FIG. 1. However, rather than having a flexible display, in this embodiment the electronic device 600 includes a first display 605 coupled to the first device housing 602 and a second display 606 coupled to the second device housing 603. Thus, in addition to separating the first device housing 602 from the second device housing 603, the hinge 601 separates the first display 605 from the second display 606 as well.

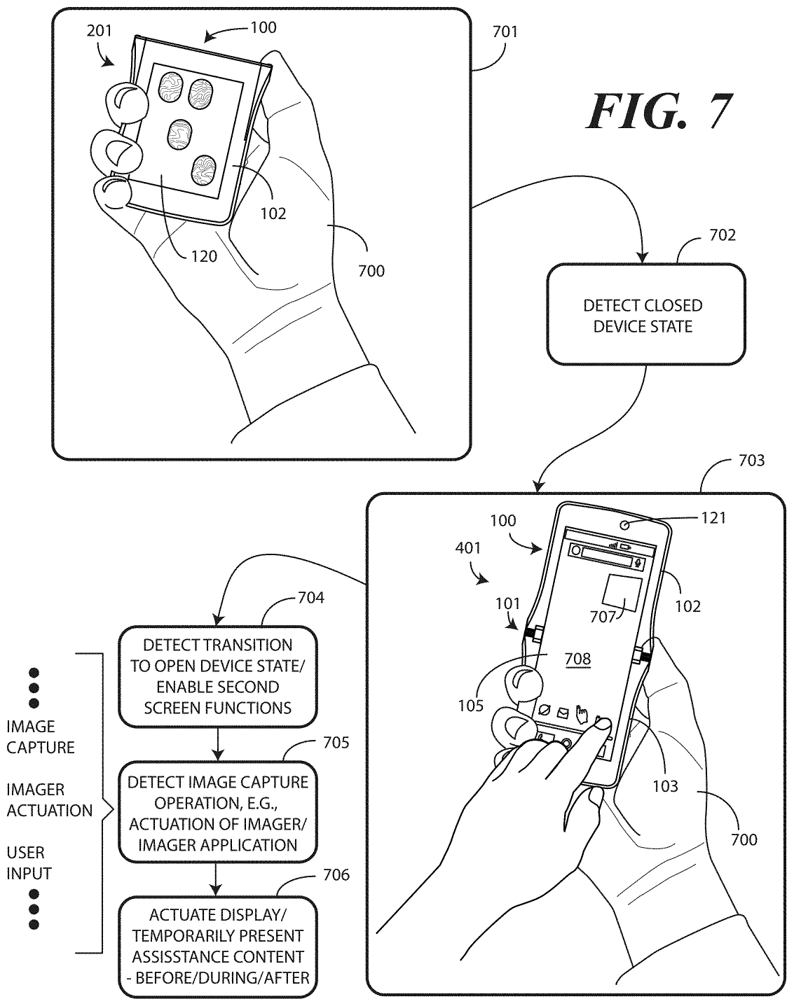

Turning now to FIG. 7, illustrated therein at step 701 is a user 700 holding the electronic device 100 of FIG. 1 while the electronic device 100 is in the closed position 201. Second display 120, which is disposed on the exterior side of the first device housing 102 is exposed and visible. By contrast, first display (105) is concealed when the electronic device 100 is in the closed position 201 due to the fact that the interior surfaces of the first device housing 102 and the second device housing (103), along which display (105) is disposed, abut when the electronic device 100 is in the closed position 201.

At step 702, the one or more processors (112), optionally using the one or more flex sensors (117) detect that the electronic device 100 is in the closed position 201. In one or more embodiments, the one or more processors (112) disable the image capture application module (111) when the electronic device 100 is in the closed position 201.

At step 703, the user 700 transitions the electronic device 100 from the closed position 201 of step 701 to the axially disposed open position 401. Specifically, the user 700 has pivoted the first device housing 102 relative to the second device housing 103 about the hinge 101 from the closed position 201 of step 701 to the axially disposed open position 401 of step 703. At step 704, the one or more processors (112), optionally in conjunction with the one or more flex sensors (117) detect that the electronic device 100 is now in the axially disposed open position 401. In one or more embodiments, upon detecting this change, the one or more processors (112) enable the image capture application module (111) at step 704.

At step 705, the image capture application module (111) and/or the one or more processors (112) detect an image capture operation. Image capture operations can include operations such as actuating an imager, launching an imager application, directing the lens of an imager toward a subject or scene that they whish to capture, and delivering user input causing the imager to one or more of actuate, capture light, focus on an object or scene, emit light from a flash, and/or capture one or more images. Other examples of image capture operations include the actuation of facial recognition algorithms of the image capture application module (111) that employ an imager to analyze light received in its field of view to identify various characteristics of a subject or scene. Still other examples of image capture operations will be obvious to those of ordinary skill in the art having the benefit of this disclosure.

The image capture operations detected at step 705 can be associated with the front facing imager, i.e., imager (106), or the rear facing imager, i.e., second imager 121. However, embodiments of the disclosure contemplate that the presentation of image capture operation assistance content is particularly useful for a subject, rather than the photographer, in cases other than selfies. Accordingly, in one or more embodiments step 705 comprises the one or more processors (112) detecting an image capture operation occurring with the front facing or exterior imager, i.e., the imager (106) that is exposed along with the exterior display when the first device housing 102 and the second device housing 103 are pivoted about the hinge 101 to the closed position 201 of step 701. In such an embodiment, examples of image capture operations detected at step 705 can include, among others, actuation of the front facing imager, receipt of user input directing the front facing imager to capture one or more images or video, capturing an image or video with an imager, the actuation of facial recognition algorithms that employ the front facing imager to analyze light received in its field of view to identify various characteristics of a subject or scene, or other operations.

In one or more embodiments, in response to detecting an image capture operation using the front facing imager at step 705, which in this embodiment occurs after detecting, at step 704, the first device housing 102 pivoting relative to the second device housing 103 from the closed position 201 of step 701 to the axially displaced open position 401 of step 703, step 705 comprises the one or more processors (112) temporarily display image capture operation assistance content on the exterior display, i.e., display (120) in this illustrative embodiment. Since the exterior display is located on the same side of the electronic device 100 as the front facing camera in the illustrative embodiment of FIG. 7, a subject looking at the front facing camera, e.g., a subject facing the back of the hand of the user 700 at step 703, is able to also see the image capture operation assistance content presented on the exterior display.

In one or more embodiments, the image capture operation assistance content is also presented on the first display 105 as well. For example, the image capture operation assistance content might be presented in a window 707 of the first display 105 while a viewfinder presentation of what the imager (106) is seeing is presented on portions 708 of the first display 105 that are complementary to the window 707. Such embodiments allow the photographer to see the image capture operation assistance content being presented to the subject in addition to what the imager (106) sees or is capturing as images or video.

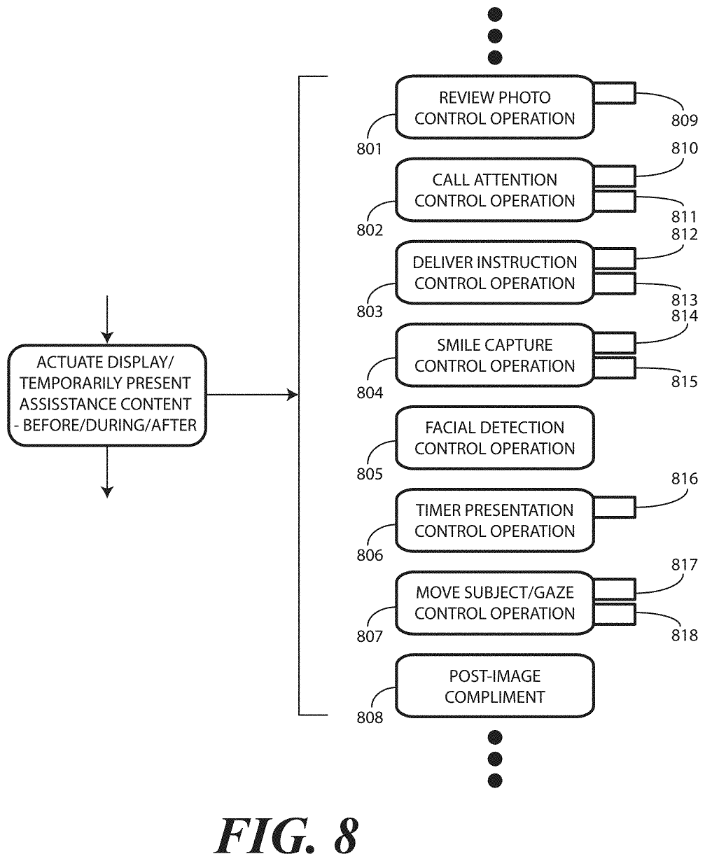

As noted above, the image capture operation assistance content can take any of a number of forms. Turning now to FIG. 8, illustrated are various examples of the forms that image capture operation assistance content can take. The examples of FIG. 8 are illustrative only, as numerous other examples of image capture operation assistance content will be obvious to those of ordinary skill in the art having the benefit of this disclosure.

In one embodiment, the image capture operation assistance content comprises review photo image capture operation assistance content 801. With review photo image capture operation assistance content 801, a picture taken by the front facing imager is presented on the exterior display 120 so that the subject of the captured image can see how they appear in the image. Thus, in one or more embodiments where the image capture operation detected is the operation of capturing an image with an imager, the image capture operation assistance content, which in this case is review photo image capture operation assistance content 801, can comprise the image 809.

In one or more embodiments, this review photo image capture operation assistance content 801 can be temporarily displayed for a predefined amount of time. Examples of the predefined amount of time include two seconds, three seconds, five seconds, ten seconds or fifteen seconds. In one or more embodiments, the predefined amount of time is a period of fifteen or fewer seconds. Other predefined periods of time for the presentation of the review photo image capture operation assistance content 801 will be obvious to those of ordinary skill in the art having the benefit of this disclosure.

In another embodiment, the image capture operation assistance content can comprise call attention image capture operation assistance content 802. In one or more embodiments, the call attention image capture operation assistance content 802 comprises one or more of an attention-calling image 810 or an attention-calling animation 811. In one or more embodiments, where the image capture operation detected is the actuation of an imager, the call attention image capture operation assistance content 802 can comprise one or more of the attention-calling image 810 or the attention-calling animation 811.

With call attention image capture operation assistance content 802, the attention-calling image 810 or the attention-calling animation 811 can comprise a funny image or animation intended to catch the attention of subjects within the field of view of the front facing camera so that their attention is turned to the electronic device. Illustrating by example, in one embodiment the call attention image capture operation assistance content 802 may comprise an animated face making googlie eyes or smiling repeatedly. Alternatively, the call attention image capture operation assistance content 802 may include an animation or video of a face yelling, “Hey You, Look Over Here!” Other examples of call attention image capture operation assistance content 802 will be described below. Still others will be obvious to those of ordinary skill in the art having the benefit of this disclosure.

In still another embodiment, the image capture operation assistance content can comprise instructional delivery image capture operation assistance content 803. In one or more embodiments, the instructional delivery image capture operation assistance content 803 comprises one or more of a pose-instructing image 812 or a pose-instructing animation 813. Thus, in one or more embodiments where the detected image capture operation comprises actuation of an imager, the instructional delivery image capture operation assistance content 803 can comprise one or more of a pose-instructing image 812 or a pose-instructing animation 813.

The instructional delivery image capture operation assistance content 803 can instruct the subject of an image to adopt a particular pose, to say something, to make certain faces, and so forth. The instructional delivery image capture operation assistance content 803 may ask a user to stand on one leg, wave their arms, jump, perform a stunt, sing, dance, play an instrument, tell a joke, recite a poem, pet their dog, make a funny face, do an impersonation, say “cheese,” perform an athletic feat, do the hokey pokey, or provide another instruction for a subject to perform. Other examples of instructional delivery image capture operation assistance content 803 will be obvious to those of ordinary skill in the art having the benefit of this disclosure.

In yet another embodiment, the image capture operation assistance content can comprise smile capture image capture operation assistance content 804. In one or more embodiments, the smile capture image capture operation assistance content 804 comprises one or more of a smile-requesting image 814 or a smile-requesting animation 815. Thus, in one or more embodiments where the detected image capture operation comprises actuation of an imager, the smile capture image capture operation assistance content 804 can comprise one or more of the smile-requesting image 814 or the smile-requesting animation 815.

With smile capture image capture operation assistance content 804, a humorous or amusing animation or image can be presented on the exterior display requesting the subject of images to smile. For example, the smile capture image capture operation assistance content 804 may comprise a video of a cat playing the piano, a dog driving a car, or a clown laughing. The smile capture image capture operation assistance content 804 may include animations of cartoon characters engaged in silly activities. This smile capture image capture operation assistance content 804 can be especially engaging with children who may be too young to understand the words, “look here and smile.”

Alternatively, for older subjects, the smile capture image capture operation assistance content 804 may simply be text, such as the word “SMILE.” Of course, as with other image capture operation assistance content configured in accordance with one or more embodiments of the disclosure, the smile capture image capture operation assistance content 804 can include combinations of text and images, be they actual still or moving images or animated still or moving images. Other examples of smile capture image capture operation assistance content 804 will be obvious to those of ordinary skill in the art having the benefit of this disclosure.

In still another embodiment, the image capture operation assistance content can comprise facial detection image capture operation assistance content 805. Embodiments of the disclosure contemplate that the presentation of image capture operation assistance content is most desirable when a person is looking generally toward the electronic device. Disabling the presentation of image capture operation assistance content can conserve battery power when, for example, taking pictures of landscapes as the plants, streams, trees, and clouds are unresponsive to any image capture operation assistance content that may be presented.

Accordingly, in one or more embodiments the facial detection image capture operation assistance content 805 comprises the temporary presentation of a detected face on the exterior display. In one or more embodiments, the one or more processors and/or image capture application module can temporarily display image capture operation assistance content only when at least one human face is within the field of view of the imager.

In another embodiment, the image capture operation assistance content comprises timer countdown image capture operation assistance content 806. As noted above, in one or more embodiments a timer can be operable with one or more processors of an electronic device. When the one or more processors detect the receipt of a user command for an imager to capture an image, in one or more embodiments the one or more processors initiate and/or start a timer upon receiving the user command.

Where the image capture operation assistance content comprises timer countdown image capture operation assistance content 806, such as when the image capture operation assistance content comprises a numeric countdown animation 816, expiration of the timer can be used to capture the image. For example, the one or more processors can cause the numeric countdown animation 816 to reach zero at the expiration of the timer. The one or more processors can then cause the imager to capture the imager when the timer expires.

With timer countdown image capture operation assistance content 806, a numeric or alphanumeric countdown, such as the presentation of the numbers 3-2-1 in succession, can be presented on the exterior display to alert the subjects as to when the exterior imager may capture the image. In one or more embodiments, when the timer countdown reaches a count of zero, the exterior imager captures the image.

The timer countdown image capture operation assistance content 806 can take other forms as well. For example, to eliminate the need to understand alphanumeric characters, in another embodiment the timer countdown image capture operation assistance content 806 comprises an animation of an hourglass with sand passing gently from the upper chamber to the lower chamber. In one or more embodiments, when all of the sand exits the upper chamber of the hourglass the exterior imager captures the image.

In still another embodiment, the timer countdown image capture operation assistance content 806 comprises an animation of a stoplight with the lights changing sequentially from red to yellow to green. In one or more embodiments, when the lights turn green, the exterior imager captures the image. These examples of timer countdown image capture operation assistance content 806 are illustrative only, as numerous others will be obvious to those of ordinary skill in the art having the benefit of this disclosure.

In still other embodiments, the image capture operation assistance content can comprise subject gaze and/or subject position image capture operation assistance content 807. In one or more embodiments, the subject gaze and/or subject position image capture operation assistance content 807 can comprise one or more of a direction-redirecting image 817 or a direction-redirecting animation 818. Thus, in one or more embodiments where the detected image capture operation comprises actuation of an imager, the subject gaze and/or subject position image capture operation assistance content 807 can comprise one or more of the direction-redirecting image 817 or the direction-redirecting animation 818.

With subject gaze and/or subject position image capture operation assistance content 807, the exterior display can draw a subject's eyes to a particular location, which may be toward the lens of the exterior camera or somewhere else. Similarly, in other embodiments, the subject gaze and/or position image capture operation assistance content 807 can direct a subject to move to a position desired by the photographer or otherwise more optimized for the image. If, for example, the photographer wants the subject to move to the left so as to be better positioned in the framed image, the exterior imager may present an arrow pointing up and to the left with the words “MOVE HERE.” Other examples of subject gaze and/or subject position image capture operation assistance content 807 will be obvious to those of ordinary skill in the art having the benefit of this disclosure.

In still another embodiment, the image capture operation assistance content can comprise post-image and/or compliment image capture operation assistance content 808. After capturing an image of a subject, the exterior display may present the words “BEAUTIFUL SHOT” or show an animation of fireworks identifying that the image capture process was highly successful. In other embodiments, the post-image and/or compliment image capture operation assistance content 808 might state, “You're beautiful—don't ever change” or include some other complimentary and inspirational message.

In still other embodiments, the post-image and/or compliment image capture operation assistance content 808 may provide an indication that the photography session is done. The post-image and/or compliment image capture operation assistance content 808 may say, “Shoots Over!” in one or more embodiments. Alternatively, it may state, “Got It, You're Done Now,” and so forth.

In one or more embodiments, this post-image and/or compliment image capture operation assistance content 808 can be temporarily displayed, such as a period of fifteen or fewer seconds. Other examples of post-image and/or compliment image capture operation assistance content 808 will be obvious to those of ordinary skill in the art having the benefit of this disclosure. Still other examples of image capture operation assistance content will also be obvious to those of ordinary skill in the art having the benefit of this disclosure.

Regardless of the type of image capture operation assistance content used, in one or more embodiments the amount of time that the image capture operation assistance content is displayed can vary. For image capture operation assistance content that is displayed after the capture of an image, such as review photo image capture operation assistance content 801 or post-image and/or compliment image capture operation assistance content 808, this image capture operation assistance content can be presented on the exterior display for a predetermined time, such as three, four, five, ten, or fifteen seconds. Other predetermined time durations will be obvious to those of ordinary skill in the art having the benefit of this disclosure.

For image capture operation assistance content presented before the capture of an image, such as the timer countdown image capture operation assistance content 806, this image capture operation assistance content can also be presented for a predetermined duration. For example, if the timer countdown image capture operation assistance content 806 comprises the numbers 3-2-1 presented serially, the predetermined time may be a period of five or ten seconds, which allow a subject to see the timer countdown image capture operation assistance content 806 without feeling nervous or anxious.

For image capture operation assistance content that is shown during the capture of an image, such as call attention image capture operation assistance content 802 or smile capture image capture operation assistance content 803, the amount of time this image capture operation assistance content is presented can vary. For example, if the image capture operation assistance content comprises an animation, this animation may be synchronized such that it is playing while the image is captured. Moreover, the image capture operation assistance content can repeat in one or more embodiments.

In one or more embodiments, the presentation of image capture operation assistance content can terminate when an image capture termination operation is detected. Illustrating by example, in one or more embodiments cessation of the presentation of image capture operation assistance content can occur when there are no longer any faces detected within the field of view of the external imager. In other embodiments, the expiration of the timer may cause the cessation of the presentation of the image capture operation assistance content. Other examples of termination events causing cessation of the presentation of image capture operation assistance content will be obvious to those of ordinary skill in the art having the benefit of this disclosure.

In one or more embodiments, the image capture operation assistance content can be used in combination. For example, in one embodiment both call attention image capture operation assistance content 802 and review photo image capture operation assistance content 801 can be used when capturing an image. The call attention image capture operation assistance content 802 can be presented for a predetermined amount of time prior to, and during the image capture operation, while the review photo image capture operation assistance content 801 can be presented for a predefined time thereafter. Similarly, both timer countdown image capture operation assistance content 806 and review photo image capture operation assistance content 801 can be used when capturing an image. The timer countdown image capture operation assistance content 806 can be presented for a predetermined amount of time prior to the image capture operation, while the review photo image capture operation assistance content 801 can be presented for a predefined time thereafter.

In still another embodiment, both timer countdown image capture operation assistance content 806 and call attention image capture operation assistance content 802 can be used when capturing an image. The timer countdown image capture operation assistance content 806 can be presented for a predetermined amount of time prior to the image capture operation while the call attention image capture operation assistance content 802 is presented when the image capture operation occurs.

Of course, three or more image capture operation assistance content examples can be used in combination. Illustrating by example, if timer countdown image capture operation assistance content 806, call attention image capture operation assistance content 802, and photo review image capture operation assistance content 801 are used in combination, the timer countdown image capture operation assistance content 806 can be presented for a predetermined amount of time prior to the image capture operation while the call attention image capture operation assistance content 802 is presented when the image capture operation occurs. Thereafter, the photo review image capture operation assistance content can be displayed for a predetermined duration, such as five to ten seconds. Other combinations of image capture operation assistance content suitable for use with embodiments of the disclosure will be obvious to those of ordinary skill in the art having the benefit of this disclosure.

It should be noted that any of the image capture operation assistance content noted above can be customized to a particular user or class of users. For instance, where the image capture application module includes a facial recognition module that analyzes images captured by the imager and/or second imager to identify facial characteristics present in images captured by the imager and/or second imager, the presentation of image capture operation assistance content can be selected or altered as a function of the facial characteristics present in the images. If, for example, a husband and wife both use the same electronic device, and the husband likes golf while the wife likes horses, when the husband is detected in the images call attention image capture operation assistance content 802 can be an animation of a golfer hitting a driver. By contrast, if the wife is detected in the images, the call attention image capture operation assistance content 802 can comprise a horse jumping a brook, and so forth. If both are detected in the images, a cartoon of a horse sinking a long putt may be presented as the call attention image capture operation assistance content 802.

In other embodiments, the image capture operation assistance content can be selected or altered as a function of a class of person found in the images. If the people are all children, the image capture operation assistance content may be in the form of a cartoon. By contrast, if everyone in the image is an adult of similar age, the image capture operation assistance content may be an image of a musician appealing to the age group, and so forth.

In one or more embodiments, the presentation of image capture operation assistance content is supported in both portrait and landscape mode just as is the presentation of captured images. Thus, when an electronic device is held in portrait mode, the image capture operation assistance content can be presented in portrait mode. By contrast, when the electronic device is rotated to landscape mode, the presentation of the image capture operation assistance content can rotate as well so that the subject always views the image capture operation assistance content right-side up.

As noted above, the functionality of presenting image capture operation assistance content is enabled, in one or more embodiments, by the configuration of the device. For instance, in one or more embodiments the image capture application module is enabled when the first device housing pivots about the hinge relative to the second device housing. In one or more embodiments, presentation of of the image capture assistance content by the one or more processors occurs only when the first device housing and the second device housing are in the axially displaced open position. When the first device housing pivots about the hinge relative to the second device housing to the closed position, the image capture application module can be disabled.

In other embodiments, additional inputs can cause the image capture application module to be disabled, thereby precluding the presentation of image capture operation assistance content. One input noted above is the presence of a facial feature within a field of view of an imager. In one or more embodiments, when there is no facial feature in the field of view of the imager, the image capture application module can be disabled. This prevents the presentation of image capture operation assistance content when, for example, a person is capturing images of a landscape.

In other embodiments, input such as light can cause the image capture application module to be disabled. Illustrating by example, where the one or more sensors of an electronic device in include a light sensor, receipt of light by the light sensor can be a condition for the image capture application module to be enabled. Said differently, in one or more embodiments, light input can be used to enable and disable the presentation of image capture operation assistance content in addition to, or instead of, the physical state of the electronic device. If, for example, the electronic device is in a low light environment, in one or more embodiments the presentation of image capture operation assistance content is disabled. This prevents the presentation of image capture operation assistance content in environments such as movie theaters. By contrast, if the electronic device is in a high light environment, in one or more embodiments the presentation of image capture operation assistance content is enabled, and so forth.

Where the image capture operation assistance content comprises an animation, e.g., where a call attention image capture operation assistance content 802 comprises the attention-calling animation 811, one or more processors of the electronic device determine how the attention-calling animation 811 is presented on the display 120. Illustrating by example, one or more playback parameters can be stored in a memory of the electronic device. The one or more processors can access these playback parameters and can cause the attention-calling animation 811, or other animation as the case may be, to be presented as a function of the playback parameters. For instance, the presentation of the animation can be timed and/or synchronized with an image capture operation.

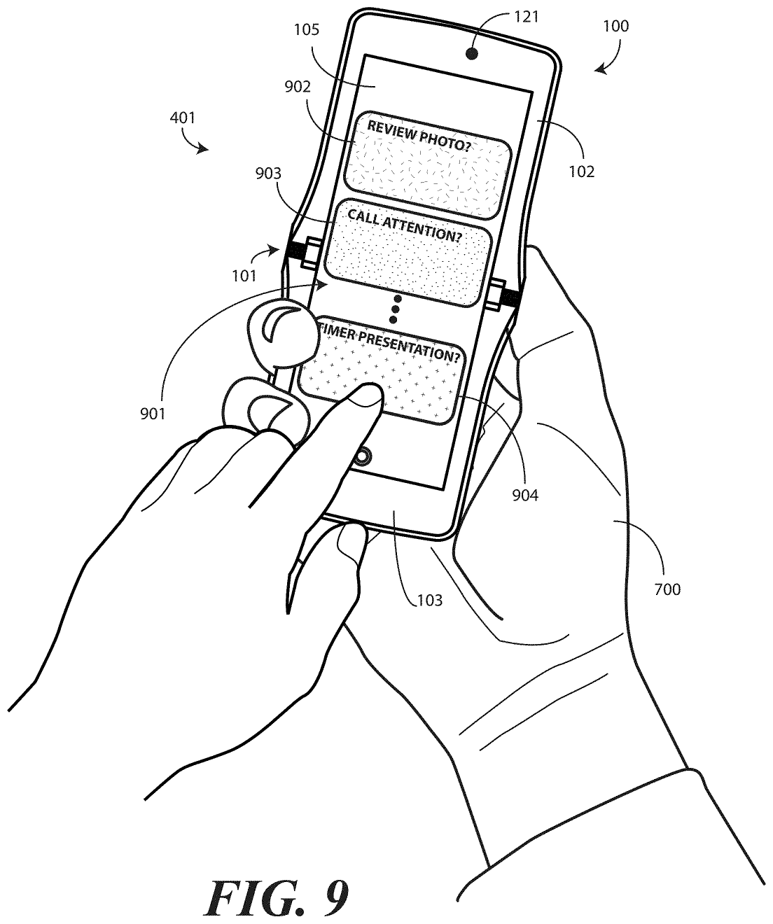

As demonstrated by FIG. 8, the image capture operation assistance content can take a variety of forms. In one or more embodiments, the electronic device enables the user to select which image capture operation assistance content option, or which combination of image capture operation assistance content options, they would like to use. Turning now to FIG. 9, illustrated therein is one way in which this can occur.

As shown in FIG. 9, the user 700 has pivoted the first device housing 102 about the hinge 101 relative to the second device housing 103 to the axially displaced open position 401. In this illustrative embodiment, this pivoting causes the one or more processors (112) of the electronic device 100 to enable the image capture application module (111), thereby allowing for the presentation of image capture operation assistance content. In the illustrative embodiment of FIG. 9, the user 700 has already performed an image capture operation by actuating the front facing imager, which is imager (106).

Since the presentation of image capture operation assistance content is enabled, the one or more processors (112) of the electronic device 100 prompt, on the display 105, for a user selection 901 of one or more image capture operation assistance content options 902,903,904 from a plurality of available image capture operation assistance content options. For instance, in one or more embodiments, upon actuating an imager (106) a menu is presented on the interior display, here display 105), allowing the user 700 to select one or more image capture operation assistance content options 902,903,904 from a plurality of image capture operation assistance content options. As shown in FIG. 9, the one or more processors (112) of the electronic device 100 then receive a user selection of the image capture assistance content from a plurality of image capture assistance content options. Thus, if the electronic device 100 provides the eight image capture operation assistance content options of FIG. 8, in one or more embodiments the user 700 can select one or more image capture operation assistance content options 902,903,904 from this plurality of image capture operation assistance content options by delivering user input to the display 105.

In other embodiments, the user 700 can store default or preferred image capture operation assistance content options in a profile stored in the memory (113) of the electronic device 100. For example, the user 700 may desire for the call attention image capture operation assistance content option 903 to be the default option used any time a facial feature is found in the field of view of the imager (106) or second imager (121) unless another selection is made. Alternatively, the user 700 may desire for the smile capture image capture operation assistance content option to be the preferred option used any time a child's facial feature is found in the field of view of the imager (106) or second imager (121) unless another selection is made, and so forth.

Embodiments of the disclosure present image capture operation assistance content before, after, or during image capture. In one or more embodiments, one or more processors of the electronic device detect an image capture event associated with capturing an image. This can include detecting activation of an imager, activation of an image capture application, delivering user input causing actuation of an image capture control, detecting a face being within a field of view of an imager, detecting a gaze direction of a face in a field of view of an imager, and so forth. In one or more embodiments, the image capture operation comprises capturing an image with an imager. In other embodiments, the image capture operation comprises actuation of the imager. In still another embodiment, the image capture operation comprises receiving a user command for the imager to capture the image. Other examples of image capture operations will be obvious to those of ordinary skill in the art having the benefit of this disclosure.

In response to detecting the image capture event, one or more embodiments of the disclosure temporarily display image capture operation assistance content on a display. In response to detecting the image capture event, one or more embodiments of the disclosure actuate the display upon which the image capture operation assistance content will be presented, and then present the image capture operation assistance content on the actuated display. In response to detecting the image capture event, one or more embodiments only present the image capture operation assistance content if the electronic device is pivoted to the axially displaced open position.

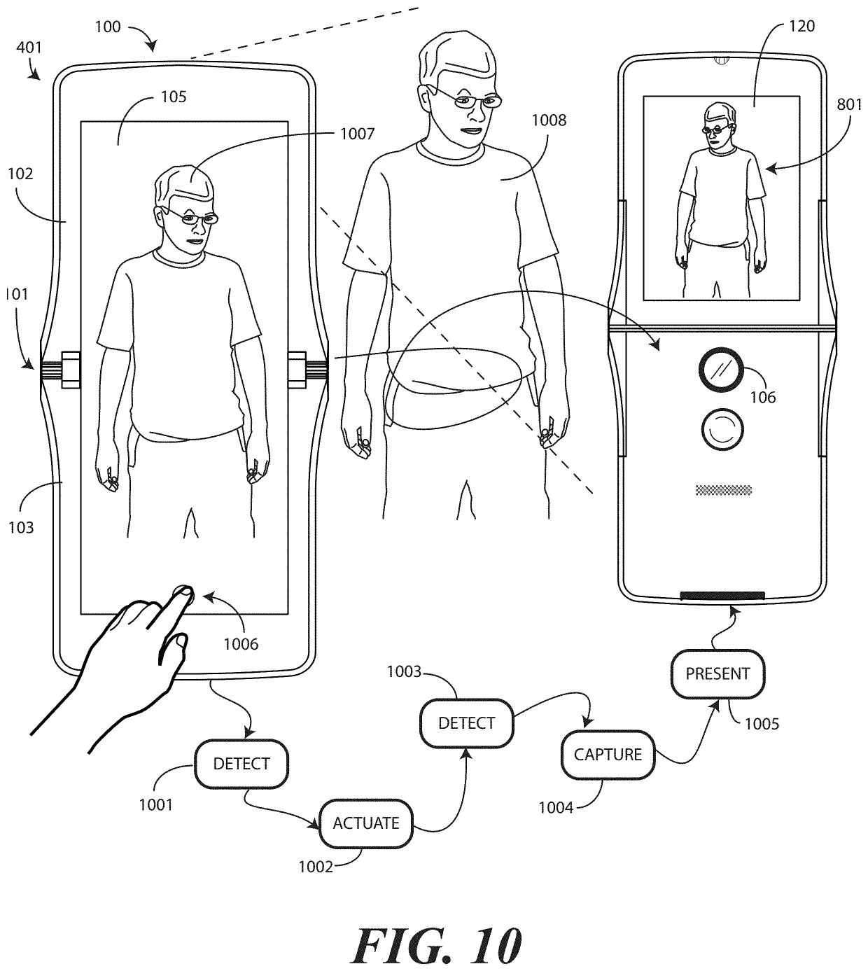

Turning now to FIG. 10, illustrated therein is one way in which this can occur. As shown in FIG. 10, the electronic device 100 has been pivoted to the axially displaced open position 401. One or more processors (112) of the electronic device 100 detect, at step 1001, the first device housing 102 pivoted about the hinge 101 relative to the second device housing 103 from the closed position (201) to the axially displaced open position 401. This results in both display 105 and display 120 being exposed. In one or more embodiments, the one or more processors (112) of the electronic device 100 enable an image capture operation assistance content presentation function at step 1001 in response to detecting the axially displaced open position 401.

Thereafter, the one or more processors (112) of the electronic device 100 detect, at step 1002, an image capture operation occurring using an imager 106 of the electronic device 100. In this illustrative embodiment, the image capture operation comprises the receipt of a user command 1006 for the imager 106 to capture an image 1007.

In one or more embodiments, at step 1003, the one or more processors (112) of the electronic device 100 actuate the display 120 facing in the same direction as the imager 106. In one or more embodiments, step 1003 occurs in response to steps 1001 and 1002, i.e., in response to the one or more processors (112) detecting the image capture operation while the first device housing 102 and the second device housing 103 are in the axially displaced open position 401.

At step 1004, the one or more processors (112) cause the imager 106 to capture the image 1007. In this illustrative embodiment, the one or more processors (112) present the image 1007 on the interior display, display 105, which was concealed when the first device housing 102 and the second device housing 103 were in the closed position (201), but is now exposed.

At step 1005, the one or more processors (112) present image capture operation assistance content on the display 120 facing the same direction as the imager 106. In this illustrative embodiment, the image capture operation assistance content comprises review photo image capture operation assistance content 801. Accordingly, in this example the review photo image capture operation assistance content 801 comprises the image 1007. Advantageously, this allows the subject 1008 of the image 1007 to review the image 1007 without the photographer needing to turn the electronic device 100 around. If the subject 1008 approves the image 1007, the photo shoot is complete. However, if the subject 1008 disapproves of the image 1007, he can simply ask the photographer to take another, in which the process can repeat.

In one or more embodiments, this review photo image capture operation assistance content 801 can be temporarily presented on the display 120 for a predefined amount of time. For example, the one or more processors (112) of the electronic device 100 may initiate a timer (122) at step 1005 for a predefined amount of time such as two seconds, three seconds, five seconds, ten seconds or fifteen seconds. In one or more embodiments, the one or more processors (112) cause the image capture operation assistance content to be presented until the timer (122) expires. In one or more embodiments, the predefined amount of time is a period of fifteen or fewer seconds. This provides the subject 1008 sufficient time to review the review photo image capture operation assistance content 801 without being rushed.

Since the image capture operation assistance content of this example is review photo image capture operation assistance content 801, in this embodiment the presentation of the review photo image capture operation assistance content 801, at step 1005, occurs after the imager 106 captures the image 1007. In other situations, the image capture operation assistance content may be presented before the imager 106 captures the image 1007, during the image capture process, or combinations of one or more of before the imager 106 captures the image 1007, during the image capture process, or after the imager 106 captures the image 1007.

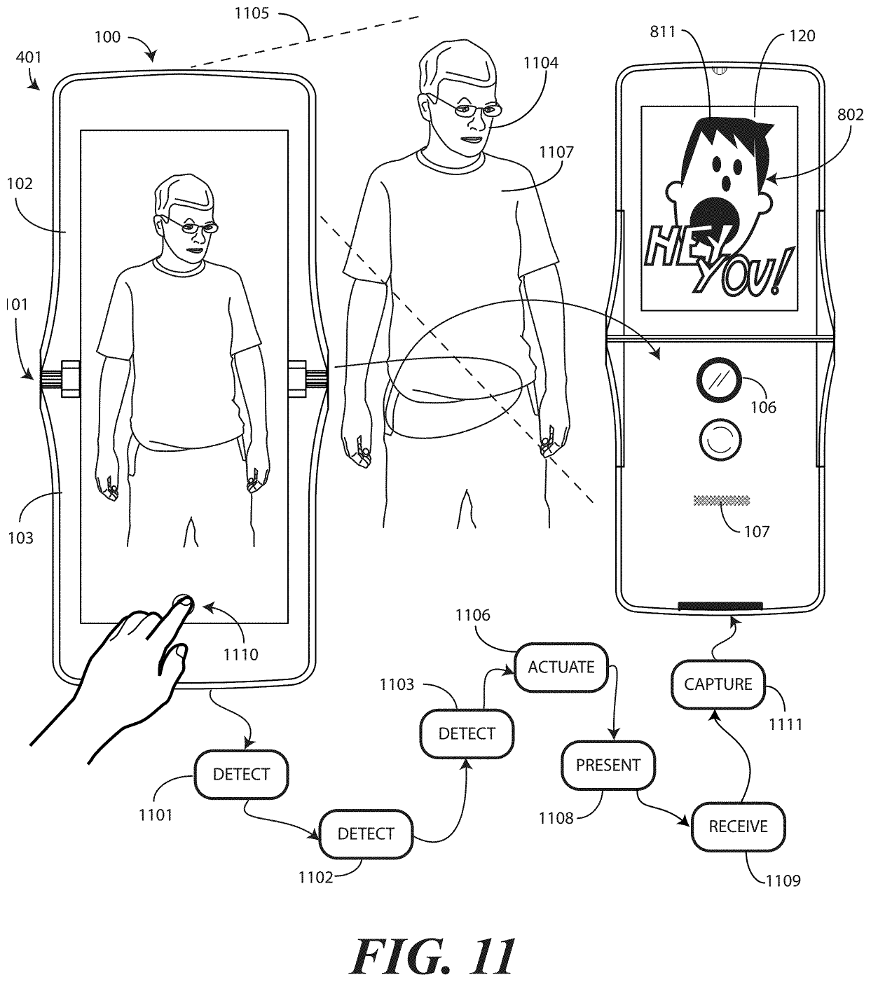

Turning now to FIG. 11, illustrated therein is another example in accordance with one or more embodiments of the disclosure. As with FIG. 10 above, the electronic device 100 has been pivoted to the axially displaced open position 401. One or more processors (112) of the electronic device 100 detect, at step 1101, the first device housing 102 pivoted about the hinge 101 relative to the second device housing 103 from the closed position (201) to the axially displaced open position 401. This results in both display 105 and display 120 being exposed.

Thereafter, the one or more processors (112) of the electronic device 100 detect, at step 1102, an image capture operation occurring using an imager 106 of the electronic device 100. In this illustrative embodiment, the image capture operation comprises the actuation of the imager 106.

At step 1103, the one or more processors (112) detect that a person's face 1104 is within a field of view 1105 of the imager 106. In one or more embodiments, the one or more processors (112) of the electronic device 100 enable an image capture operation assistance content presentation function at step 1103 in response to detecting that the person's face 1104 is within the field of view 1105 of the imager 106.

In one or more embodiments, at step 1106, the one or more processors (112) of the electronic device 100 actuate the display 120 facing in the same direction as the imager 106. In one or more embodiments, step 1106 occurs in response to steps 1102 and 1103, i.e., in response to the one or more processors (112) detecting the image capture operation and in response to the person's face 1104 being within the field of view 1105 of the imager 106.

Unfortunately, the subject 1107 fails to be aware of the fact that the photographer wishes to take a picture of him Accordingly, the subject 1107 fails to look directly at the imager 106. This can be frustrating to the photographer, causing them to have to yell to get the attention of the subject 1107.

Fortunately, the electronic device 100 is configured in accordance with one or more embodiments of the disclosure. To obviate the need for the photographer to have to yell, at step 1108 the one or more processors (112) of the electronic device 100 present image capture operation assistance content on the display 120. In this illustrative embodiment, the image capture operation assistance content comprises call attention image capture operation assistance content 802.

In this example, to capture the attention of the subject 1107, the one or more processors (112) present an attention-calling animation 811 on the display 120 of a computer generated “talking head” yelling “hey you,” with audible sounds saying, “hey you” being emitted by the speaker port 107. Advantageously, this draws the attention of the subject 1107 toward the imager 106.

Thereafter, or alternatively prior, the one or more processors (112) of the electronic device 100 receive, at step 1109, a user command 1110 for the imager 106 to capture an image. In one or more embodiments, where step 1109 precedes step 1108, the presentation of the image capture operation assistance content occurring at step 1108 occurs in response to the receipt of the user command 1110. In other embodiments, presentation of the image capture operation assistance content can occur in response to facial detection, as previously described.

In one or more embodiments, the one or more processors (112) monitor the field of view 1105 to detect when the face 1104 of the subject 1107 is looking at the imager 106. During this time, the one or more processors (112) maintain the presentation of the call attention image capture operation assistance content 802 until both the face 1104 of the subject 1107 is directed toward the imager 106 and the imager 106 captures the image at step 1111. Thus, in one or more embodiments where the image capture operation detected at step 1102 comprises actuation of the imager 106, and where step 1109 comprises receiving, by the one or more processors (112), the user command 1110 for the imager 106 to capture an image, the presentation of the call attention image capture operation assistance content 802 continues until one or both of the subject 1107 looks at the imager 106 and/or the imager 106 captures an image.

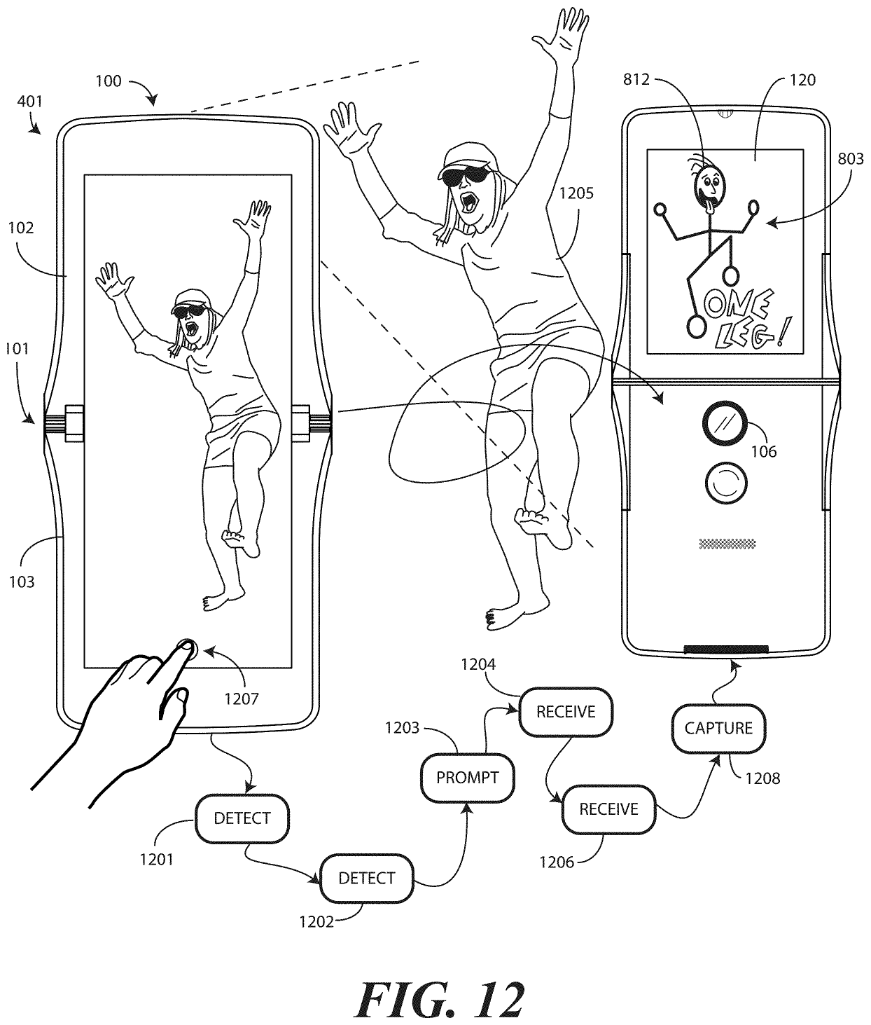

Turning now to FIG. 12, illustrated therein is another method in accordance with one or more embodiments of the disclosure. As shown in FIG. 12, the electronic device 100 has once again been pivoted to the axially displaced open position 401. One or more processors (112) of the electronic device 100 detect, at step 1201, the first device housing 102 pivoted about the hinge 101 relative to the second device housing 103 from the closed position (201) to the axially displaced open position 401. This results in both display 105 and display 120 being exposed.

In one or more embodiments, the one or more processors (112) of the electronic device 100 enable an image capture operation assistance content presentation function at step 1201 in response to detecting the axially displaced open position 401. In one or more embodiments, the presentation of the image capture assistance content occurs only when the first device housing 102 and the second device housing 103 are in the axially displaced open position 401.

Thereafter, the one or more processors (112) of the electronic device 100 detect, at step 1202, an image capture operation occurring using an imager 106 of the electronic device 100. In this illustrative embodiment, the image capture operation comprises the actuation of the imager 106. However, as noted above, the image capture operation can take a variety of other forms. The image capture operation can be various types of user input or events corresponding to the process of capturing an image. These include receiving a user command to capture an image, selection of an image capture control setting, selecting a imager aperture or shutter setting, or identifying whether a subject or the face of a subject is within a field of view of the imager 106. Other examples of image capture operations will be obvious to those of ordinary skill in the art having the benefit of this disclosure.

At step 1203, the one or more processors (112) of the electronic device 100 prompt, on display 105, for a user selection of the image capture assistance content from a plurality of image capture assistance content options as described above with reference to FIG. 9. At step 1204, the one or more processors (112) of the electronic device 100 receive a user selection of the image capture assistance content from a plurality of image capture assistance content options.

In this illustrative example, the image capture operation assistance content comprises instructional delivery image capture operation assistance content 803. In this example, the instructional delivery image capture operation assistance content 803 comprises a computer generated pose-instructing image 812 of a really goofy actor standing on one leg with his tongue sticking out above the phrase “one leg!” This pose-instructing image 812 instructs the subject 1205 to mimic the really goofy actor, which she promptly does.

Thereafter, the one or more processors (112) of the electronic device 100 receive, at step 1206, a user command 1207 for the imager 106 to capture an image. The imager 106 captures the image at step 1208. In one or more embodiments, the presentation of the instructional delivery image capture operation assistance content 803 continues until the imager 106 captures an image.

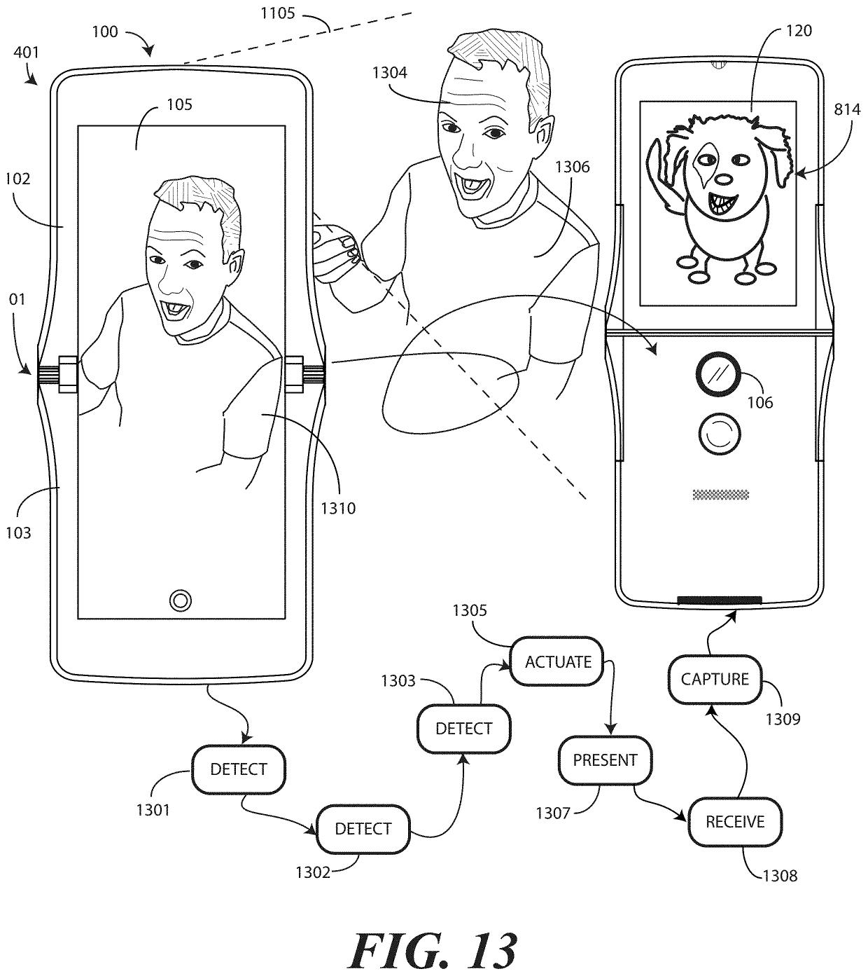

Turning now to FIG. 13, illustrated therein is another method in accordance with one or more embodiments of the disclosure. As shown in FIG. 13, the electronic device 100 has once again been pivoted to the axially displaced open position 401. One or more processors (112) of the electronic device 100 detect, at step 1301, the first device housing 102 pivoted about the hinge 101 relative to the second device housing 103 from the closed position (201) to the axially displaced open position 401. This results in both display 105 and display 120 being exposed.

In one or more embodiments, the one or more processors (112) of the electronic device 100 enable an image capture operation assistance content presentation function at step 1301 in response to detecting the axially displaced open position 401. In one or more embodiments, the presentation of the image capture assistance content occurs only when the first device housing 102 and the second device housing 103 are in the axially displaced open position 401.

Thereafter, the one or more processors (112) of the electronic device 100 detect, at step 1302, an image capture operation occurring using an imager 106 of the electronic device 100. In this illustrative embodiment, the image capture operation comprises the actuation of the imager 106.

At step 1303, the one or more processors (112) detect that a person's face 1304 is within a field of view 1105 of the imager 106. In one or more embodiments, the one or more processors (112) of the electronic device 100 require that the person's face 1304 be within the field of view 1105 of the imager 106 to enable the image capture operation assistance content presentation function. In one or more embodiments, at step 1305, the one or more processors (112) of the electronic device 100 actuate the display 120 facing in the same direction as the imager 106.

Unfortunately, the subject 1306 initially fails to smile, and instead appears to be generally frustrated, tired, and grim. To correct this situation, at step 1307 the one or more processors (112) of the electronic device 100 present image capture operation assistance content on the display 120. In this illustrative embodiment, the image capture operation assistance content comprises smile capture image capture operation assistance content 804, and in particular smile-requesting content comprising a smile-requesting image 814 of a dog with a gleeful, but silly, smile. Seeing the dog, the subject 1306 instantly begins smiling, and even gestures toward the display 120.

Thereafter, or alternatively prior, the one or more processors (112) of the electronic device 100 receive, at step 1308, a user command for the imager 106 to capture an image. In one or more embodiments, where step 1308 precedes step 1307, the presentation of the image capture operation assistance content occurring at step 1307 occurs in response to the receipt of the user command. In other embodiments, presentation of the image capture operation assistance content can occur in response to the imager 106 detecting that there is no smile on the face of the subject 1306.

In one or more embodiments, the one or more processors (112) monitor the field of view 1105 to detect when a smile appears on the face 1304 of the subject 1306 while the subject 1306 is looking at the imager 106. During this time, the one or more processors (112) maintain the presentation of the smile capture image capture operation assistance content 804. When the smile is detected, the imager 106 captures the image 1310 at step 1309, and presents the image 1310 on the display 105 for photographer review.

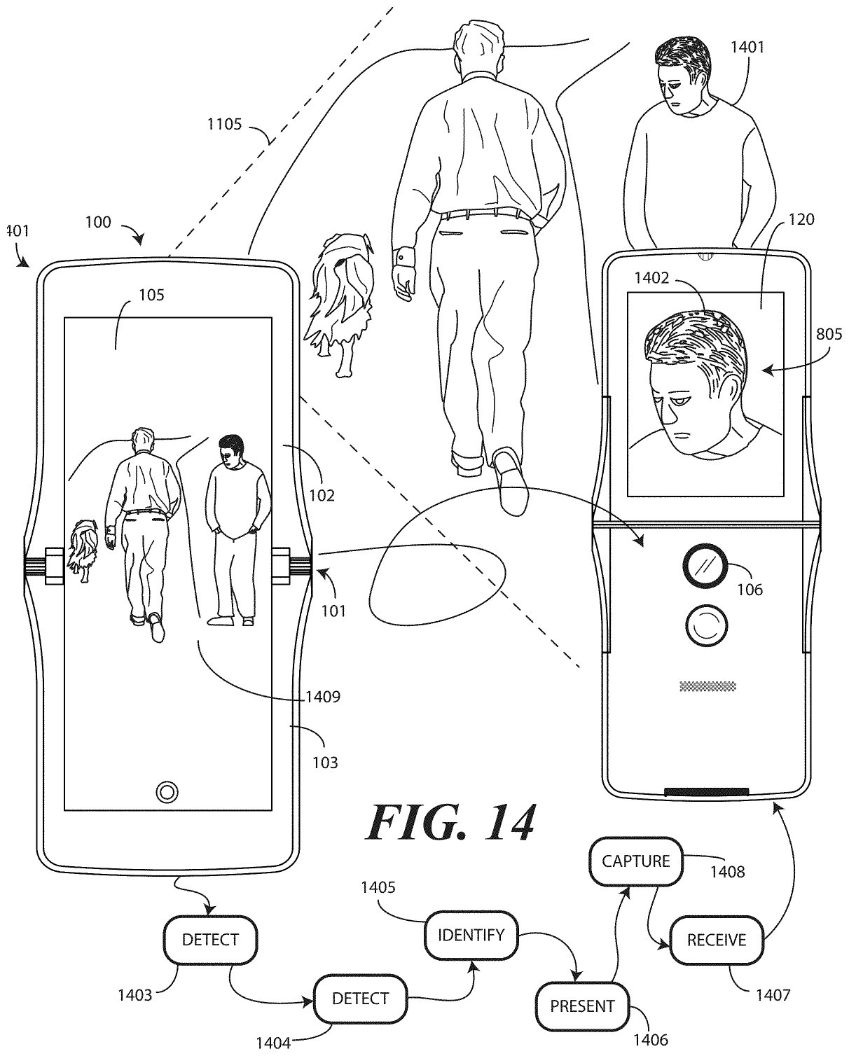

Turning now to FIG. 14, illustrated therein is another method in accordance with one or more embodiments of the disclosure. In one or more embodiments, one or more processors (112) of the electronic device identify, using the imager 106, whether at least one human face 1401 is within a field of view 1105 of the imager 106. In one or more embodiments, the one or more processors (112) temporarily display the image capture operation assistance content, which in this example is a zoomed in image 1402 of the human face 1401, on the display 120 only when the at least one human face 1401 is within the field of view 1105 of the imager 106. Such is the case in FIG. 14.

As shown in FIG. 14, the electronic device 100 has once again been pivoted to the axially displaced open position 401. One or more processors (112) of the electronic device 100 detect, at step 1403, the first device housing 102 pivoted about the hinge 101 relative to the second device housing 103 from the closed position (201) to the axially displaced open position 401. This results in both display 105 and display 120 being exposed.

Thereafter, the one or more processors (112) of the electronic device 100 detect, at step 1404, an image capture operation occurring using an imager 106 of the electronic device 100. In this illustrative embodiment, the image capture operation comprises the actuation of the imager 106.

At step 1405, one or more processors (112) of the electronic device 100 identify, using the imager 106, whether at least one human face 1401 is within a field of view 1105 of the imager 106. In one or more embodiments, the presentation of the image capture assistance content occurs only when the human face 1401 is within a field of view 1105 of the imager 106.

At step 1406, the one or more processors (112) of the electronic device 100 present image capture operation assistance content on the display 120. In this illustrative example, the image capture operation assistance content comprises facial detection image capture operation assistance content 805. Thereafter, the one or more processors (112) of the electronic device 100 receive, at step 1407, a user command for the imager 106 to capture an image. The imager 106 captures the image 1409 at step 1408 and presents the image 1409 on the display 105.

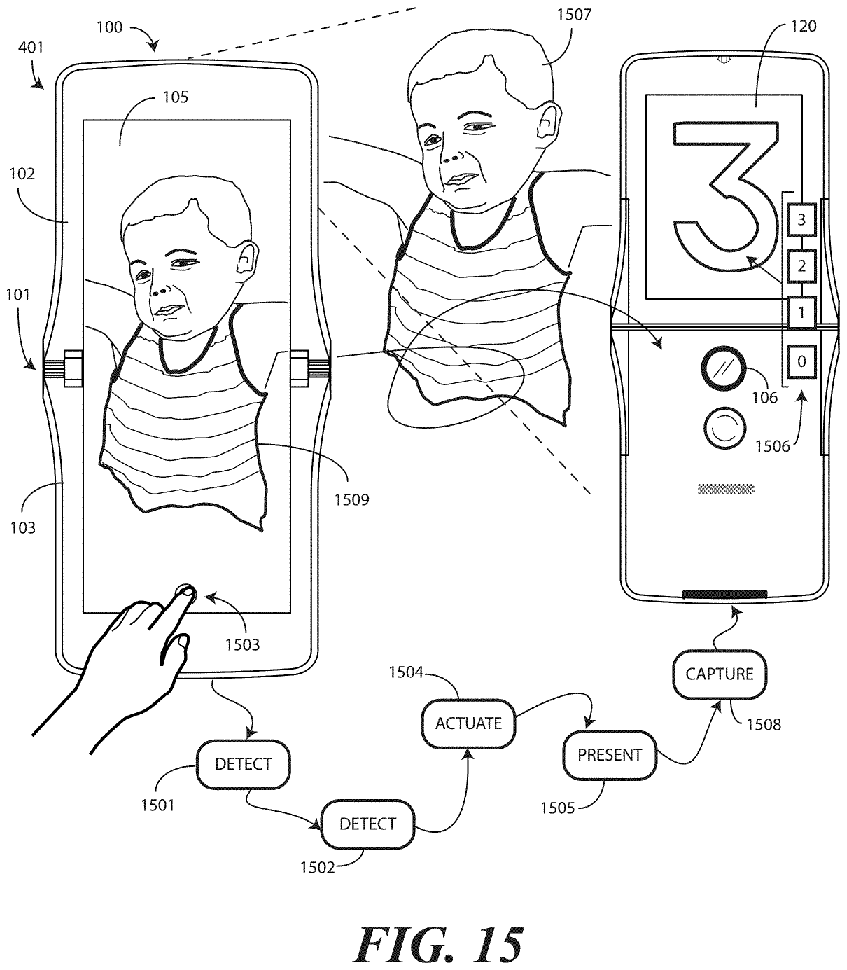

Turning now to FIG. 15, illustrated therein is another method in accordance with one or more embodiments of the disclosure. As shown in FIG. 15, the electronic device 100 has once again been pivoted to the axially displaced open position 401. One or more processors (112) of the electronic device 100 detect, at step 1501, the first device housing 102 pivoted about the hinge 101 relative to the second device housing 103 from the closed position (201) to the axially displaced open position 401. This results in both display 105 and display 120 being exposed.

In one or more embodiments, the one or more processors (112) of the electronic device 100 enable an image capture operation assistance content presentation function at step 1501 in response to detecting the axially displaced open position 401. In one or more embodiments, the presentation of the image capture assistance content occurs only when the first device housing 102 and the second device housing 103 are in the axially displaced open position 401.

Thereafter, the one or more processors (112) of the electronic device 100 detect, at step 1502, an image capture operation occurring using an imager 106 of the electronic device 100. In this illustrative embodiment, the image capture operation comprises the receipt of a user command 1503 for the imager 106 to capture an image.

At step 1504, the one or more processors (112) initialize or actuate a timer (122). At step 1505, the one or more processors (112) present image capture operation assistance content on the display 120. In this illustrative embodiment, the image capture operation assistance content comprises a numeric countdown animation 1506. In the numeric countdown animation 1506, the numbers 3-2-1-0 are presented sequentially on the display 120. This allows the subject 1507, despite being a child, to know exactly when the imager 106 will capture an image, thereby allowing them to be prepared by striking a cool pose.

In one or more embodiments, step 1508 comprises the one or more processors (112) causing the imager 106 to capture the image 1509 when the numeric countdown animation 1506 reaches zero. Said differently, in the illustrative embodiment of FIG. 15, where the image capture operation detected at step 1502 comprises receiving a user command 1503 for the imager 106 to capture the image 1509, the one or more processors (112) initiate the timer (122) in response to receiving the user command 1503. The presentation of the image capture assistance information, here the numeric countdown animation 1506, then occurs until the timer (122) expires and the image 1509 is captured at step 1508. The image 1509 can then be presented on the display 105 for review by the photographer.

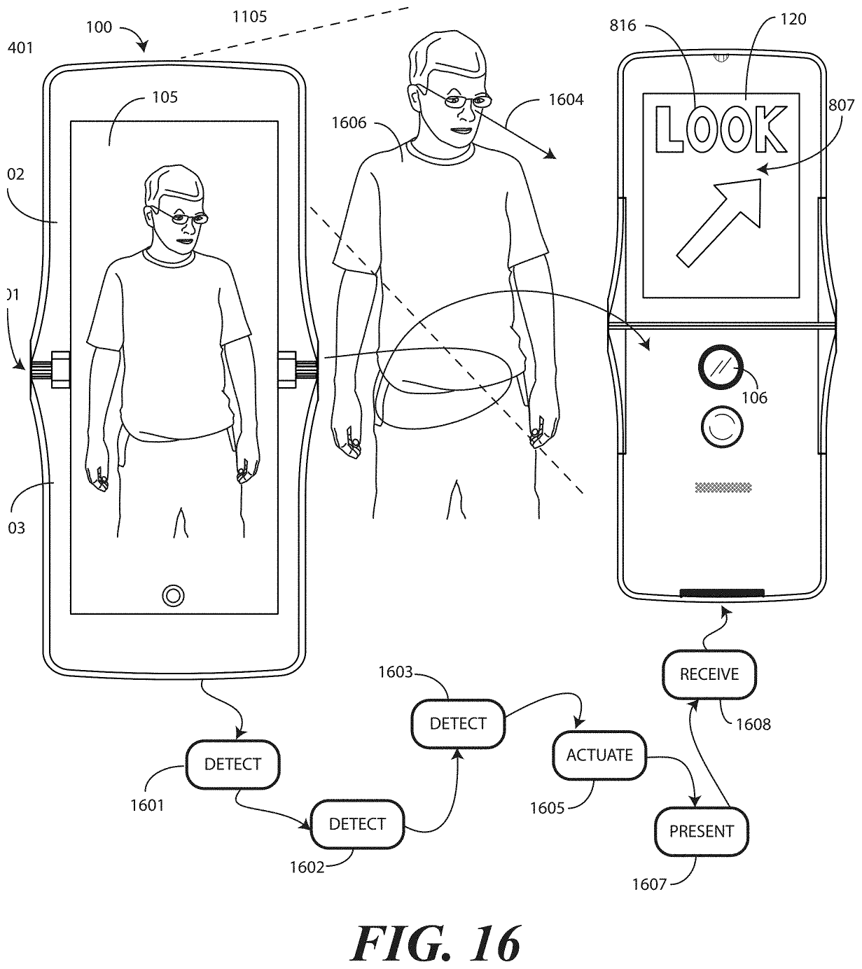

Turning now to FIG. 16, illustrated therein is another method in accordance with one or more embodiments of the disclosure. As shown in FIG. 16, the electronic device 100 has once again been pivoted to the axially displaced open position 401. One or more processors (112) of the electronic device 100 detect, at step 1601, the first device housing 102 pivoted about the hinge 101 relative to the second device housing 103 from the closed position (201) to the axially displaced open position 401. This results in both display 105 and display 120 being exposed.

In one or more embodiments, the one or more processors (112) of the electronic device 100 enable an image capture operation assistance content presentation function at step 1601 in response to detecting the axially displaced open position 401. In one or more embodiments, the presentation of the image capture assistance content occurs only when the first device housing 102 and the second device housing 103 are in the axially displaced open position 401.

Thereafter, the one or more processors (112) of the electronic device 100 detect, at step 1602, an image capture operation occurring using an imager 106 of the electronic device 100. In this illustrative embodiment, the image capture operation comprises the actuation of the imager 106.

At step 1603, the one or more processors (112) detect that a person's gaze 1604 not directed toward the imager 106. In one or more embodiments, the one or more processors (112) of the electronic device 100 require that the person's gaze 1604 be directed toward the imager 106 for an image to be captured. In one or more embodiments, in response to detecting that the person's gaze 1604 is directed somewhere other than at the imager 106, at step 1605 the one or more processors (112) of the electronic device 100 actuate the display 120 facing in the same direction as the imager 106.

Since the subject 1606 initially fails to direct his gaze 1604 toward the imager 106, at step 1607 the one or more processors (112) of the electronic device 100 present image capture operation assistance content on the display 120. In this illustrative embodiment, the image capture operation assistance content comprises subject gaze and/or subject position image capture operation assistance content 807. In this example, the subject gaze and/or subject position image capture operation assistance content 807 comprises a direction-redirecting image 816.

In this illustrative embodiment, the direction-redirecting image 816 draws the subject's gaze 1604 toward the lens of the imager 106. Had the subject 1606 been only partially within the field of view 1105 of the imager 106, the subject gaze and/or position image capture operation assistance content 807 may have directed the subject 1606 to physically move to a position desired by the photographer or otherwise more optimized for the image.

Thereafter, or alternatively prior, the one or more processors (112) of the electronic device 100 receive, at step 1608, a user command for the imager 106 to capture an image. In one or more embodiments, where step 1608 precedes step 1607, the presentation of the image capture operation assistance content occurring at step 1607 occurs in response to the receipt of the user command. In other embodiments, presentation of the image capture operation assistance content can occur in response to the imager 106 detecting that the subject's gaze 1604 is not directed at the imager 106.

In one or more embodiments, the one or more processors (112) monitor the field of view 1105 to detect when the subject's gaze 1604 is directed at the imager 106. During this time, the one or more processors (112) maintain the presentation of the subject gaze and/or subject position image capture operation assistance content 807 on the display 120. When the subject's gaze 1604 becomes redirected at the imager 106, the imager 106 captures the image at step 1309.

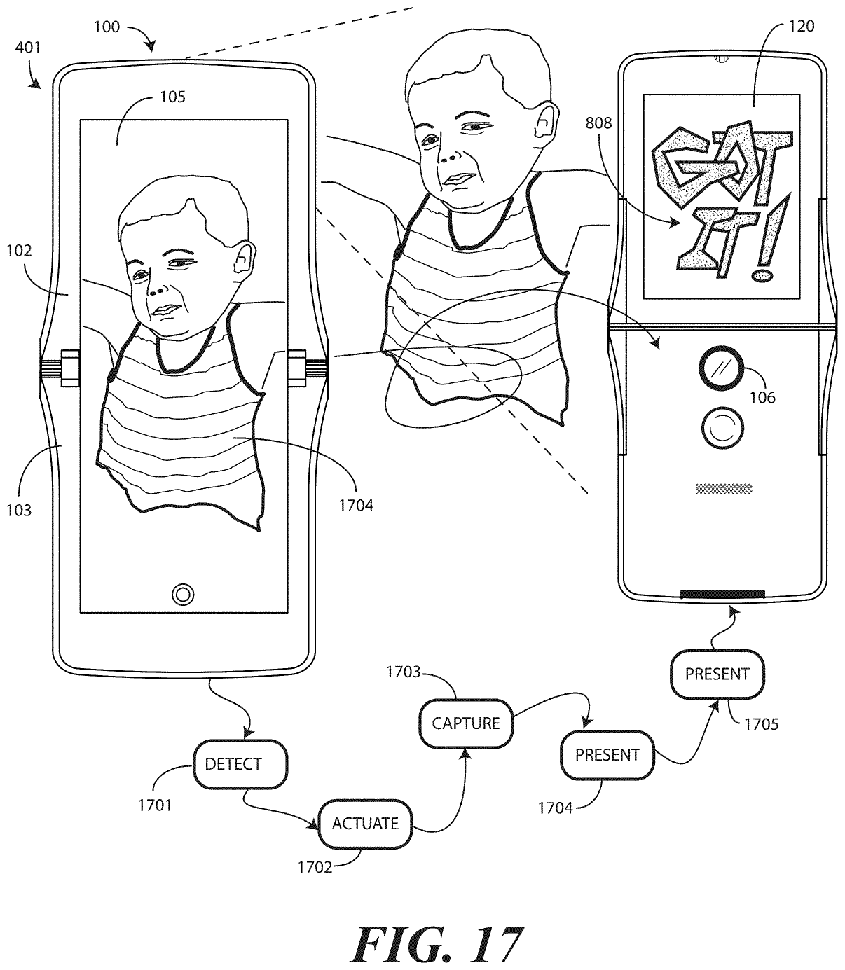

Turning now to FIG. 17, illustrated therein is another example in accordance with one or more embodiments of the disclosure. At step 1701, one or more processors (112) of an electronic device 100 pivoted to an axially displaced open position 401 detect an image capture operation occurring using an imager 106 of the electronic device 100. In this illustrative embodiment, the image capture operation comprises the receipt of a user command for the imager 106 to capture an image.

In one or more embodiments, at step 1702, the one or more processors (112) of the electronic device 100 actuate the display 120 facing in the same direction as the imager 106. At step 1703, the one or more processors (112) cause the imager 106 to capture the image 1704. In this illustrative embodiment, the one or more processors (112) present the image 1704 on the interior display, display 105, which was concealed when the first device housing 102 and the second device housing 103 were in the closed position (201), but is now exposed.

At step 1705, the one or more processors (112) present image capture operation assistance content on the display 120 facing the same direction as the imager 106. In this illustrative embodiment, the image capture operation assistance content comprises post-image and/or compliment image capture operation assistance content 808. In this example, the post-image and/or compliment image capture operation assistance content 808 comprises the words, “Got it!,” confirming that the photographer actually captured the desired photograph. In other embodiments, the post-image and/or compliment image capture operation assistance content 808 might state, “You're beautiful—don't ever change” or include some other complimentary and inspirational message.

In one or more embodiments, this post-image and/or compliment image capture operation assistance content 808 can be temporarily displayed, such as a period of fifteen or fewer seconds. For example, the one or more processors (112) of the electronic device 100 may initiate a timer (122) for a predefined amount of time such as two seconds, three seconds, five seconds, ten seconds or fifteen seconds. In one or more embodiments, the one or more processors (112) cause the image capture operation assistance content to be presented until the timer (122) expires.

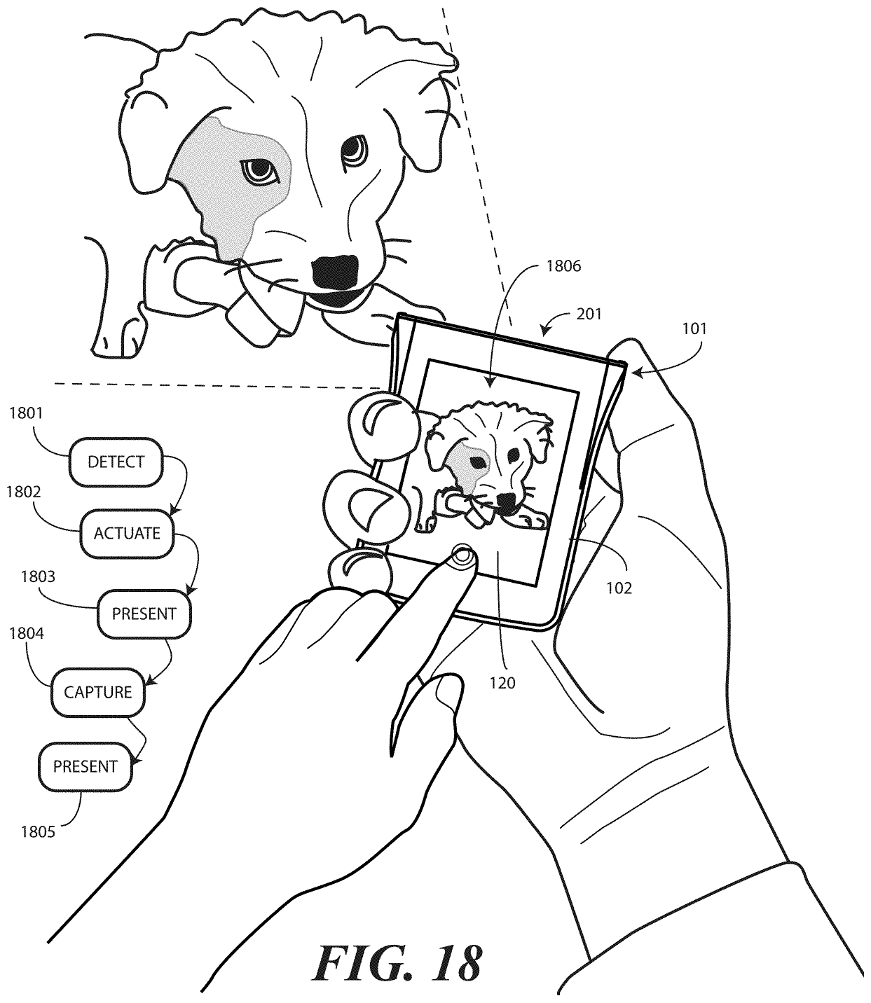

Turning now to FIG. 18, illustrated therein is another method in accordance with one or more embodiments of the disclosure. Recall from above that in one or more embodiments the feature of presenting image capture operation assistance content on an exterior display is enabled only when the first device housing 102 is pivoted about a hinge 101 relative to the second device housing 103 to the axially displaced open position 401, but is precluded when the first device housing 102 is pivoted about the hinge 101 relative to the second device housing 103 to the closed position 201. Such is the case in FIG. 18.

At step 1801, one or more processors (112) of an electronic device 100 pivoted to the closed position 201 detect an image capture operation occurring using an imager 106 of the electronic device 100. In this illustrative embodiment, the image capture operation comprises the receipt of a user command for the imager 106 to capture an image.

In one or more embodiments, at step 1802, the one or more processors (112) of the electronic device 100 actuate the display 120 facing in the same direction as the imager 106. At step 1803, the one or more processors (112) present imager viewfinder content 1806 on the display. Accordingly, rather than presenting image capture operation assistance content on the exterior display, in this embodiment the display 120 is used simply as a viewfinder since the electronic device 100 is pivoted to the closed position 201.

The one or more processors (112) cause the imager 106 to capture the image at step 1804. The one or more processors (112) can then present the image on the exterior display, display 120, for review by the photographer at step 1805.

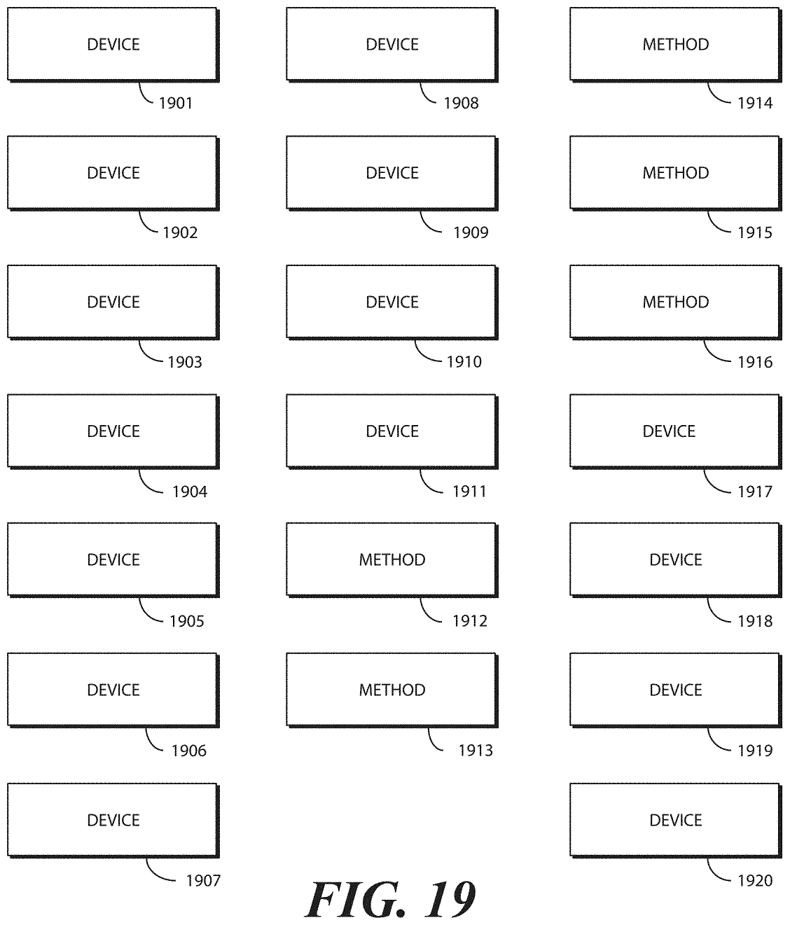

Turning now to FIG. 19, illustrated therein are various embodiments of the disclosure. At 1901, an electronic device comprises a first device housing and a second device housing. At 1901, a hinge couples the first device housing to the second device housing. At 1901, the first device housing is pivotable about the hinge relative to the second device housing between a closed position and an axially displaced open position.

At 1901, the electronic device includes a display and an imager. At 1901, each of the display and the imager is coupled to one of the first device housing or the second device housing. At 1901 the display and the imager are exposed when the first device housing and the second device housing are in the closed position.

At 1901, the electronic device includes one or more processors operable with the imager and the display. At 1901, the one or more processors, in response to detecting an image capture operation using the imager occurring after detecting the first device housing pivoting relative to the second device housing from the closed position to the axially displaced open position, temporarily display image capture operation assistance content on the display.

At 1902, the image capture operation of 1901 comprises capturing an image with the imager. At 1902, the image capture operation assistance content comprises the image.

At 1903, the image capture operation of 1901 comprises actuation of the imager. At 1903 the image capture assistance content comprises one or more of an attention-calling image or an attention-calling animation.

At 1904, the image capture operation of 1901 comprises actuation of the imager. At 1904 the image capture assistance content comprises one or more of a smile-requesting image or a smile-requesting animation.

At 1905, the image capture operation of 1901 comprises actuation of the imager. At 1905, the image capture assistance content comprises one or more of a pose-instructing image or a pose-instructing animation.

At 1906, the image capture operation of 1901 comprises actuation of the imager. At 1906 the image capture assistance content comprises one or more of a direction-redirecting image or a direction-redirecting animation.

At 1907, the electronic device of 1901 further comprises a timer operable with the one or more processors. At 1907, the image capture operation comprises receiving a user command for the imager to capture an image. At 1907, the one or more processors initiate the timer upon receiving the user command. At 1907, the image capture assistance content comprises a numeric countdown animation. At 1908, the numeric countdown animation of 1907 reaches zero at expiration of the timer. At 1908, the one or more processors cause the imager to capture the image when the timer expires.

At 1909, the electronic device of 1901 further comprises at least one other display coupled to one of or more the first device housing or the second device housing. At 1909, the at least one other display is concealed when the first device housing and the second device housing are in the closed position. At 1909, the image capture operation comprises receiving a user command for the imager to capture an image. At 1909, the one or more processors display the image on the at least one other display.

At 1910, the one or more processors identify, using the imager, whether at least one human face is within a field of view of the imager. At 1910, the one or more processors temporarily display the image capture operation assistance content on the display only when the at least one human face is within the field of view of the imager.

At 1911, the electronic device of 1901 further comprises at least one other display coupled to one of or more the first device housing or the second device housing. At 1911, the at least one other display is concealed when the first device housing and the second device housing are in the closed position. At 1911, the one or more processors prompt, on the at least one other display, for a user selection of the image capture assistance content from a plurality of image capture assistance content options.

At 1912, a method in an electronic device comprises detecting, by one or more processors, a first device housing pivoted about a hinge relative to a second device housing from a closed position, where a display is exposed and at least one other display is concealed, to an axially displaced open position, where the display and at least one other display are both exposed. Thereafter, at 1912, the method comprises detecting, by the one or more processors, an image capture operation using an imager of the electronic device occurring.

At 1912, the method comprises actuating, by the one or more processors in response to detecting the image capture operation while the first device housing and the second device housing are in the axially displaced open position, the display. At 1912, the method comprises presenting, by the one or more processors, image capture assistance content on the display.

At 1913, the image capture operation of 1912 comprises actuation of the imager. At 1913, the image capture assistance content comprises attention-calling content. At 1913, the method further comprises receiving, by the one or more processors, a user command for the imager to capture an image. At 1913, the presenting of the attention-calling content on the display continues until the imager captures the image.

At 1914, the image capture operation of 1912 comprises actuation of the imager. At 1914, the image capture assistance content comprises smile-requesting content. At 1914, the method further comprises receiving, by the one or more processors, a user command for the image to capture an image. At 1914, the presenting of the smile-requesting content on the display continues until the imager captures the image.

At 1915, the image capture operation of 1912 comprises actuation of the imager. At 1915, the image capture assistance content comprises a numeric countdown animation. At 1915, the method further comprises receiving, by the one or more processors, a user command for the image to capture an image. At 1915, the one or more processors causes the imager to capture the image when the numeric countdown animation reaches zero.

At 1916, the image capture operation of 1912 comprises receiving, by the one or more processors, a user command for the imager to capture an image. At 1916, the image capture assistance content comprises the image.

At 1917, an electronic device comprises a first device housing and a second device housing. At 1917, the first device housing and the second device housing are pivotable about a hinge between a closed position and an axially displaced open position.

At 1917, the electronic device comprises a display and an imager, each coupled to one of the first device housing or the second device housing such that the display and the imager are exposed when the first device housing and the second device housing are in the closed position. At 1917, the electronic device comprises one or more processors operable with the imager.

At 1917, the one or more processors detect an image capture operation and present, in response to detecting the image capture operation, image capture assistance content on the display. At 1917, the presenting of the image capture assistance content occurs only when the first device housing and the second device housing are in the axially displaced open position.

At 1918, the image capture operation of 1917 comprises receiving a user command for the imager to capture the image. At 1918, the presenting of the image capture assistance content occurs after the imager captures the image.

At 1919, the one or more processors of 1917 receive a user selection of the image capture assistance content from a plurality of image capture assistance content options.

At 1920, the electronic device of 1917 further comprises a timer. At 1920, the image capture operation comprises receiving a user command for the imager to capture the image. At 1920, the one or more processors initiate the timer in response to receiving the user command. At 1920, the presenting the image capture assistance information occurring until the timer expires.

In the foregoing specification, specific embodiments of the present disclosure have been described. However, one of ordinary skill in the art appreciates that various modifications and changes can be made without departing from the scope of the present disclosure as set forth in the claims below. Thus, while preferred embodiments of the disclosure have been illustrated and described, it is clear that the disclosure is not so limited. Numerous modifications, changes, variations, substitutions, and equivalents will occur to those skilled in the art without departing from the spirit and scope of the present disclosure as defined by the following claims.

Accordingly, the specification and figures are to be regarded in an illustrative rather than a restrictive sense, and all such modifications are intended to be included within the scope of present disclosure. The benefits, advantages, solutions to problems, and any element(s) that may cause any benefit, advantage, or solution to occur or become more pronounced are not to be construed as a critical, required, or essential features or elements of any or all the claims.

1. An electronic device, comprising:
a first device housing and a second device housing;
a hinge coupling the first device housing to the second device housing, the first device housing pivotable about the hinge relative to the second device housing between a closed position and an axially displaced open position;
a display and an imager, each coupled to one of the first device housing or the second device housing, the display and the imager exposed when the first device housing and the second device housing are in the closed position; and
one or more processors operable with the imager and the display, the one or more processors, in response to detecting an image capture operation using the imager occurring after detecting the first device housing pivoting relative to the second device housing from the closed position to the axially displaced open position, identifying, using the imager, whether at least one human face is within a field of view of the imager and temporarily displaying image capture operation assistance content on the display only when the at least one human face is within the field of view of the imager.

2. The electronic device of claim 1, the image capture operation comprising capturing an image with the imager, the image capture operation assistance content comprising the image.

3. The electronic device of claim 1, the image capture operation comprising actuation of the imager, the image capture assistance content comprising one or more of an attention-calling image or an attention-calling animation.

4. The electronic device of claim 1, the image capture operation comprising actuation of the imager, the image capture assistance content comprising one or more of a smile-requesting image or a smile-requesting animation.

5. The electronic device of claim 1, the image capture operation comprising actuation of the imager, the image capture assistance content comprising one or more of a pose-instructing image or a pose-instructing animation.

6. The electronic device of claim 1, the image capture operation comprising actuation of the imager, the image capture assistance content comprising one or more of a direction-redirecting image or a direction-redirecting animation.

7. The electronic device of claim 1, further comprising a timer operable with the one or more processors, the image capture operation comprising receiving a user command for the imager to capture an image, the one or more processors initiating the timer upon receiving the user command, the image capture assistance content comprising a numeric countdown animation.

8. The electronic device of claim 7, the numeric countdown animation reaching zero at expiration of the timer, and the one or more processors causing the imager to capture the image when the timer expires.

9. The electronic device of claim 1, further comprising at least one other display coupled to one of or more the first device housing or the second device housing, the at least one other display concealed when the first device housing and the second device housing are in the closed position, the image capture operation comprising receiving a user command for the imager to capture an image, the one or more processors displaying the image on the at least one other display.

10. The electronic device of claim 1, the one or more processors temporarily displaying the image capture operation assistance content on the display only when the first device housing and the second device housing are in the axially displaced open position.

11. The electronic device of claim 1, further comprising at least one other display coupled to one of or more the first device housing or the second device housing, the at least one other display concealed when the first device housing and the second device housing are in the closed position, the one or more processors prompting, on the at least one other display, for a user selection of the image capture assistance content from a plurality of image capture assistance content options.

12. A method in an electronic device, the method comprising:
detecting, by one or more processors, a first device housing pivoted about a hinge relative to a second device housing from a closed position, where a display is exposed and at least one other display is concealed, to an axially displaced open position, where the display and at least one other display are both exposed;
thereafter, detecting, by the one or more processors, an image capture operation using an imager of the electronic device occurring;
actuating, by the one or more processors in response to detecting the image capture operation while the first device housing and the second device housing are in the axially displaced open position, the display; and
presenting, by the one or more processors, image capture assistance content on the display, the image capture assistance content comprising attention-calling content prior to executing the image capture operation.

13. The method of claim 12, the image capture operation comprising actuation of the imager, the attention-calling content configured to catch the attention of subjects within a field of view of the imager so that their attention is turned to the electronic device, further comprising receiving, by the one or more processors, a user command for the imager to capture an image, wherein the presenting of the attention-calling content on the display continues until the imager captures the image.

14. The method of claim 12, the image capture operation comprising actuation of the imager, the image capture assistance content comprising smile-requesting content, further comprising receiving, by the one or more processors, a user command for the image to capture an image, wherein the presenting of the smile-requesting content on the display continues until the imager captures the image.

15. The method of claim 12, the image capture operation comprising actuation of the imager, the image capture assistance content comprising a numeric countdown animation, further comprising receiving, by the one or more processors, a user command for the image to capture an image, the one or more processors causing the imager to capture the image when the numeric countdown animation reaches zero.

16. The method of claim 12, the image capture operation comprising receiving, by the one or more processors, a user command for the imager to capture an image, the image capture assistance content comprising the image.

17. An electronic device, comprising:
a first device housing and a second device housing, pivotable about a hinge between a closed position and an axially displaced open position;
a display and an imager, each coupled to one of the first device housing or the second device housing such that the display and the imager are exposed when the first device housing and the second device housing are in the closed position; and
one or more processors operable with the imager, the one or more processors detecting an image capture operation and presenting, in response to detecting the image capture operation, image capture assistance content on the display;
wherein the presenting of the image capture assistance content occurs only when the first device housing and the second device housing are in the axially displaced open position.

18. The electronic device of claim 17, the image capture operation comprising receiving a user command for the imager to capture the image, wherein the presenting of the image capture assistance content occurs after the imager captures the image.

19. The electronic device of claim 17, the one or more processors receiving a user selection of the image capture assistance content from a plurality of image capture assistance content options.

20. The electronic device of claim 17, further comprising a timer, the image capture operation comprising receiving a user command for the imager to capture the image, the one or more processors initiating the timer in response to receiving the user command, the presenting the image capture assistance information occurring until the timer expires.
